(19) United States
(12) Patent Application Publication
(10) Pub. No.: US 2004/0125893 A1
(43) Pub. Date: Jul. 1, 2004

(54) Methods and systems for tracking of amplitudes, phases and frequencies of a multi-component sinusoidal signal

(76) Inventor: Saeed Gazor, Kingston (CA)

Correspondence Address: SMART & BIGGAR/FETHERSTONHAUGH & CO., P.O. BOX 2999, STATION D, 55 METCALFE STREET, OTTAWA, ON, K1P5Y6, CA

(21) Appl. No.: 10/736,697

(22) Filed: Dec. 17, 2003

Related U.S. Application Data
(60) Provisional application No. 60/433,808, filed on Dec. 17, 2002.

(51) Int. Cl. H03C 1/00

(52) U.S. Cl. 375/324; 332/150

(57) ABSTRACT

System and methods are provided based on optimization of the weighted log-likelihood. These systems are able to efficiently track dominant sinusoidal components of a real signal in Gaussian noise, provided that the number of the components is known. The algorithm is implemented using simple parallel building blocks involving narrow-band filters that are adaptively self-tuned around the frequencies of the signal components. The algorithm has low computational complexity and provides high estimation accuracy and is also able to track chirp signals. The algorithm is flexible enough to be adjusted to operate in different environments such as for speech signals, by selecting a proper window function. Simulation results confirm that the proposed algorithm is reliable in tracking the frequencies as well as in estimation of the amplitudes of the components. In a chirp environment, the algorithm is able to recognize some frequency cross-overs as long as the amplitudes are different enough around the cross-over moment. Simulations show that the LIR of the algorithm is not affected by the SNR and is inversely proportional to the window length. The effects of the length and type of the window on the frequency resolution and the LIR of the algorithm are discussed. The algorithm is efficiently capable of decomposing speech voiced signals.

### RELATED APPLICATIONS

This application claims the benefit of U.S. Provisional Application No. 60/433,808 filed Dec. 17, 2002.

### FIELD OF THE INVENTION

The present invention relates generally to the decomposition of an observed signal into its constituent components and, in particular, to the estimation and tracking of characteristic parameters of the constituent components of the observed signal.

### BACKGROUND OF THE INVENTION

The estimation of the characteristic parameters of a dominant sinusoidal component of a received signal is a common feature within radio receivers and many other systems. The characteristic parameters of the dominant sinusoidal component are typically required to facilitate the demodulation and extraction of information carried by the received signal.

In radio communications Amplitude Modulation (AM) and Frequency Modulation (FM) are commonly used, either in conjunction with one another or independently. If either FM or AM is used exclusively, it is frequency or complex amplitude information, respectively, that is to be extracted from the received signal that has been corrupted after traversing a transmission medium (i.e. a channel). Thus, a single independent demodulation method for either FM or AM would suffice.

However, a more challenging problem is to devise a method to estimate both the complex amplitude (amplitude and phase) and the frequency of multiple dominant sinusoidal components of a signal, or to devise a radio receiver that can, for a number of prominent sinusoids contained in a received signal, estimate the complex amplitude and frequency of each of the prominent sinusoids contained in the received signal. Such methods have applications in the field of speech-processing, for example speech recognition and speech decomposition. By decomposing a speech signal into a set of amplitudes, frequencies and phases of the dominant sinusoidal components, speech information can be efficiently stored or transmitted and then reconstructed after being read from a memory, or after being transmitted and received.

Given the already complex nature of this problem it is usually assumed that the environment (i.e. channel) and the parameters to be estimated are reasonably stationary. In other words, it is assumed that the statistical characteristics of the channel and the received signal do not change significantly over a short duration of time.

Different approaches have been used to address the problem of estimating both the complex amplitude and frequency of each of a number of prominent frequency components contained in a received signal. The many approaches employed include the use of the Discrete Fourier Transform (DFT), Adaptive Line Enhancement (ALE), Extended Kalman Filter (EKF), Maximum Likelihood Estimation (MLE), and Joint Time Frequency Analysis (JTFA).

The DFT was one of the first methods employed because it readily enabled the separation of the prominent sinusoidal components in the frequency domain. This method is particularly suitable in applications where the parameters are constant, as the DFT can be used in concert with the MLE approach. The combination of the DFT and MLE approaches results in a method that is the equivalent of maximizing the periodgram spectrum. Using DFT and MLE approaches together, the periodgram can be calculated and maximized at discrete frequency points. The prominent components of the received signal can be operated upon independently, avoiding cross-interference between them.

The combined DFT and MLE method outlined above is not very attractive for real time applications because of the high computational cost and complexity associated with the method. Also, because the method has no memory the tracking is not efficient. Several methods have been suggested to enhance the performance of this approach, however they have been employed with diminishing returns and do not completely resolve the problems. For instance, the hidden Markov model was proposed to improve the efficiency of tracking the parameters and the computational cost of this approach can be reduced by use of the Fast Fourier Transform (FFT), in place of the DFT.

The MLE method on its own is a powerful approach to parameter estimation and is widely used in signal processing. An iterative method for the MLE extraction of parameters of a harmonic series using the Expectation Maximization (EM) algorithm, where the number of harmonics is assumed to be known, has been suggested for AWGN (Additive White Gaussian Noise) channels with known noise variance. Such methods suffer from poor performance because the effect of the cross-interference of harmonics is ignored. These cross-interferences become significant contributors to the degradation of a signal within a low SNR (signal-to-noise ratio) environment or for a short data length.

If the characteristic parameters of the signal are slightly non-stationary or if the additive noise has a time varying variance, employing an approach that relies on finite length window, such as the DFT, will inherently lead to the loss of some information in regard to the dynamics of the signal. In previous works using the harmonic model for a speech signal, the amplitudes, phases and frequencies that make-up the speech signal have been estimated. Furthermore, it has also been shown that information about the nature of the slowly time varying parameters can be obtained from the distortions caused by windowing.

In yet another approach called Adaptive Line Enhancement (ALE), the frequency of the dominant component is estimated by minimizing the output energy of a notch filter. An Adaptive Comb Filter (ACF) that is an extension of ALE has been used to estimate the frequency of harmonic signals.

Kalman Filtering has also been employed in prior work for different scenarios. Specifically, EKF has been used to track the frequencies, the amplitudes and the phases of harmonic components within a periodic signal corrupted by AWGN. Using similar principles, several non-linear filters have been proposed for the decomposition of signals that are modeled as a sum of jointly modulated amplitude and frequency cosines in an additive noise environment, where the centre frequencies are very slowly time varying. Furthermore, assuming that the noise statistics and the number of superimposed signals are known, an EKF can be designed to track frequency formats of speech.

In another existing approach the signal to be analyzed is assumed to be a Polynomial Phase Signal (PPS) and unknown parameters are estimated. Several techniques could be employed to resolve this problem, such as FFT. High-resolution frequency estimation methods such as Kumaresan-Tufts, MUSIC and Matrix Pencil are alternatives to estimate the polynomial phase coefficients.

Exponentially-damped Polynomial Phase Signals (EPPS) have been treated as a special case of PPS's. In such a case, it is typically assumed that a PPS can be modeled as having constant amplitude, thus allowing the use of JTFA tools such as Wigner-Ville distribution and an associated Ambiguity Function. Using the Wigner-Ville distribution an estimation method that selects an optimal time domain window length to resolve the trade-off between the estimation bias and the variance of the unknown frequency can be used.

In another existing approach researchers have considered non-stationary signals as time-dependent ARMA (auto-regressive moving average) processes, and suggested a general estimation procedure for the ARMA parameters using a set of basis functions. In one such work, estimates for the signal parameters for any non-stationary signal can be obtained using the Non-linear Instantaneous Least Squares (NILS) method. NILS has relation with ML as well as with signal-subspace fitting and linear prediction based estimation approaches.

### SUMMARY OF THE INVENTION

According to one broad aspect, the invention provides a method of tracking amplitude, phase and frequency of a plurality of sinusoidal components in a signal, the method comprising: a) processing the signal to produce a new set of amplitude and phase estimates using a weighted likelihood method; and b) processing the signal to produce a new set of frequency estimates using a weighted likelihood method.

In some embodiments, the method further comprises sampling the signal to produce a sequence of real-valued samples, wherein steps a) and b) are performed in the digital domain.

In some embodiments, the method further comprises sampling the signal to produce a sequence of complex-valued samples, wherein steps a) and b) are performed in the digital domain.

In some embodiments, steps a) and b) are performed in the continuous time domain.

According to one broad aspect, the invention provides a method of tracking amplitude, phase and frequency of a plurality of sinusoidal components in a signal, the method comprising: for a current update period: i) processing the signal to produce a new set of complex amplitude estimates by: a) for a first input set of estimated complex sinusoidal components, separating components to produce component estimates; ii) processing the signal to produce a new set of estimated complex sinusoidal components by: b) for each component of a second input set of estimated complex sinusoidal components, estimating a frequency deviation estimate; c) adapting a previous set of frequency estimates taking into account an input set of component estimates and the frequency deviation estimates to produce a new set of frequency estimates; and d) converting the new set of frequency estimates to a new set of estimated complex sinusoidal components.

In some embodiments, the signal is a sequence of samples and processing is done in the digital domain.

In some embodiments, the processing is done in the continuous time domain.

In some embodiments, the further comprises: performing cross-interference cancellation on the component estimates to produce a new set of cross-interference cancelled component estimates, and using the new set of cross-interference cancelled estimates as the input set of component estimates in an execution of step c).

In some embodiments, the method further comprises: performing complex envelope extraction on the component estimates to produce a new set of complex amplitude estimates.

In some embodiments, the method further comprises: performing complex envelope extraction on the cross-interference cancelled component estimates to produce a new set of complex amplitude estimates.

In some embodiments, for the first input set of estimated complex sinusoidal components, separating components to produce component estimates is done using a weighted log-likelihood function with a first weighting sequence; for each of the second input set of estimated complex sinusoidal components, estimating the frequency deviation estimate is done using a weighted log-likelihood function with a second weighting sequence.

In some embodiments, the first and second weighting sequences are the same.

In some embodiments, step i) comprises a first half-iteration, and step ii) comprises a second half iteration, one first half-iteration and one second half-iteration comprising a complete iteration and wherein for each update period, a plurality of complete iterations are performed to produce the new set of complex amplitude estimates and the new set of estimated complex sinusoidal components.

In some embodiments, the first input set of estimated complex sinusoidal components and the second set of estimated complex sinusoidal components are initially set to initial values, and thereafter are set to estimated complex sinusoidal components produced by a previous iteration of the method.

In some embodiments, for each update of the complex amplitude and frequency: the step of processing samples of the sequence of samples to produce a new set of complex amplitude estimates is performed before the step of processing the sequence of samples to produce a new set of estimated complex sinusoidal components; the first input set and the second input set of estimated complex sinusoidal components comprise the new set of estimated complex sinusoidal components determined during a previous update period; wherein the input set of cross-interference cancelled estimates comprises the new set of cross-interference cancelled estimates determined during the current update period.

In some embodiments, for each update of the amplitude, phase and frequency: the step of processing the signal to produce a new set of estimated complex sinusoidal components is performed before the step of processing the sequence of samples to produce a new set of complex amplitude estimates; the input set of component estimates comprises the set of cross-interference cancelled estimates determined during a previous update period; the first input set of estimated complex sinusoidal components comprises the new set of estimated complex sinusoidal components determined during the current update period and the second input set of estimated complex sinusoidal components comprises the new set of estimated complex sinusoidal components determined during a previous update period.

In some embodiments, for the first input set of estimated complex sinusoidal components, performing component extraction using a weighted log-likelihood function with the first weighting sequence comprises filtering the samples with a respective component extraction filter tuned to a respective one of the first input set of estimated complex sinusoidal components.

In some embodiments, performing cross-interference cancellation on the component estimates to produce a new set of cross-interference cancelled component estimates comprises multiplying the component estimates by a cross-interference cancellation matrix.

In some embodiments, performing complex envelope extraction on the cross-interference cancelled component estimates to produce the new set of complex amplitude estimates comprises multiplying each cross-interference cancelled component estimate by the respective estimated complex sinusoidal component with negative exponent.

In some embodiments, for each of the second input set of estimated complex sinusoidal components, estimating a frequency deviation estimate using the weighted log-likelihood function with the second weighting sequence comprises filtering the sampled sequence with a respective frequency deviation filter tuned to the estimated complex sinusoidal component.

In some embodiments, adapting the previous set of frequency estimates taking into account an input set of component estimates and the frequency deviation estimates to produce a new set of frequency estimates comprises applying an adaptation value to each previous frequency estimate, the adaptation value being a function of both the input set of component estimates and the frequency deviation estimates.

In some embodiments, applying an adaptation value to each previous frequency estimate, the adaptation value being a function of both the input set of component estimates and the frequency deviation estimates comprises: determining a partial derivative with respect to each estimated complex sinusoidal component of a function based on the weighted log-likelihood function; for each frequency estimate, determining the adaptation value from the respective partial derivative.

In some embodiment, adapting the previous set of frequency estimates taking into account the input set of component estimates and the frequency deviation estimates to produce the new set of frequency estimates comprises: applying an adaptation value to each frequency estimate in the previous set of frequency estimates, the adaptation value being a function of both the component estimates and the frequency deviation estimates to produce an intermediate set of frequency estimates; using the frequency deviation estimates and previous frequency deviation estimates to produce an estimate of chirp for each sinusoidal component; for each sinusoidal component, combining the frequency deviation estimate and the estimate of chirp to produce a new frequency estimate.

In some embodiments, converting the new set of frequency estimates to new estimated complex sinusoidal components comprises combining previous estimated complex sinusoidal component estimates with the new frequency estimates.

In some embodiments, combining the previous estimated complex sinusoidal component estimates with the new frequency estimates comprises: multiplying each previous estimated complex sinusoidal component estimate by e\hat{ }(j×new frequency estimate).

In some embodiments, one or more ASICs (application specific integrated circuit) adapts to implement a method.

In some embodiments, one or more DSPs (digital signal processors) adapts to implement a method.

In some embodiments, one or more FPGAs (field programmable gate arrays) adapts to implement a method.

In some embodiments, one or more general purpose processors adapts to implement a method.

In some embodiments, a combination of at least two circuits selected from a group consisting of ASIC, FPGA, DSP, and general purpose processor adapts to implement a method.

In some embodiments, a computer readable medium having executable code embodied therein for causing a processing platform to execute a method.

According to one broad aspect, the invention provides an apparatus for tracking amplitude, phase and frequency of a plurality of sinusoidal components in a signal, the apparatus comprising: a first processing path adapted to process the signal to produce a new set of amplitude and phase estimates using a weighted likelihood method; and a second processing path adapted to process the signal to produce a new set of frequency estimates using a weighted likelihood method.

In some embodiments, the apparatus further comprises: a sampler adapted to sample the signal to produce a sequence of real-valued samples, wherein the first and second processing paths perform signal processing in the digital domain.

In some embodiments, an apparatus further comprises: a sampler adapted to sample the signal to produce a sequence of complex-valued samples, wherein the first and second processing paths perform signal processing in the digital domain.

In some embodiments, the first and second processing paths perform signal processing in the continuous time domain.

According to one broad aspect, the invention provides an apparatus for tracking amplitude, phase and frequency of a plurality of sinusoidal components in a signal, the apparatus comprising: at least one component extraction filter adapted process the signal to produce component estimates for each of a first input set of estimated complex sinusoidal components, each component extraction filter being tuned to a respective one of the first input set of estimated complex sinusoidal components; at least one frequency deviation filter adapted to process the signal to produce a frequency deviation estimate for each of a second input set of estimated complex sinusoidal components, each frequency deviation filter being tuned to a respective one of the second input set of estimated complex sinusoidal components; at least one adaptive frequency tracker adapted to produce a new set of frequency estimates by adapting a previous set of frequency estimates taking into account an input set of component estimates and the frequency deviation estimates; and at least one component generator adapted convert the new set of frequency estimates to a new set of estimated complex sinusoidal components.

In some embodiments, the signal is a sequence of samples and processing is done in the digital domain, and wherein the at least one component generator comprises at least one digital controlled oscillator.

In some embodiments, the apparatus further comprises: a cross-interference canceller adapted to perform cross-interference cancellation on the component estimates to produce a new set of cross-interference cancelled component estimates; wherein the new set of cross-interference cancelled estimates are used as the input set of component estimates to the adaptive frequency tracker.

In some embodiments, the apparatus further comprises: at least one complex envelope estimator adapted to perform complex envelope extraction on the component estimates to produce a new set of complex amplitude estimates.

In some embodiments, the apparatus further comprises: at least one complex envelope estimator adapted to perform complex envelope extraction on the cross-interference cancelled component estimates to produce a new set of complex amplitude estimates.

In some embodiments, each component extraction filter implements a weighted log-likelihood function with a first weighting sequence; each frequency deviation filter implements a weighted log-likelihood function with a second weighting sequence.

In some embodiments, the first and second weighting sequences are the same.

In some embodiments, the first input set of estimated complex sinusoidal components and the second set of estimated complex sinusoidal components are initially set to initial values, and thereafter are set to previously determined estimated complex sinusoidal components.

In some embodiments, for each time a new set of complex amplitude estimates is produced by the apparatus: the component extraction filter(s) operate to produce the new set of complex amplitude estimates before the frequency deviation filter(s) operate to produce the new set of estimated complex sinusoidal components; the first input set and the second input set of estimated complex sinusoidal components comprise the new set of estimated complex sinusoidal components determined during a previous update period; wherein the input set of cross-interference cancelled estimates comprises the new set of cross-interference cancelled estimates determined during the current update period.

In some embodiments, for each time a new set of complex amplitude estimates is produced by the apparatus: the component extraction filter(s) operate to produce the new set of estimated complex sinusoidal components before the frequency deviation filters operate to produce the new set of complex amplitude estimates; the input set of component estimates comprises the set of cross-interference cancelled estimates determined during a previous update period; the first input set of estimated complex sinusoidal components comprises the new set of estimated complex sinusoidal components determined during the current update period and the second input set of estimated complex sinusoidal components comprises the new set of estimated complex sinusoidal components determined during a previous update period.

In some embodiments, the cross-interference canceller produces the new set of cross-interference cancelled component estimates by multiplying the component estimates by a cross-interference cancellation matrix.

In some embodiments, the complex envelope estimator(s) produce the new set of complex amplitude estimates by multiplying each cross-interference cancelled component estimate by the respective estimated complex sinusoidal component with negative exponent.

In some embodiments, the adaptive frequency tracker(s) apply an adaptation value to each previous frequency estimate, the adaptation value being a function of both the component estimates and the frequency deviation estimates.

In some embodiments, the adaptive frequency tracker(s) determine a partial derivative with respect to each estimated complex sinusoidal component of a function based on a weighted log-likelihood function and for each frequency estimate, determine the adaptation value from the respective partial derivative.

In some embodiments, the adaptive frequency tracker(s) produce a new set of frequency estimates by applying an adaptation value to each frequency estimate in a previous set of frequency estimates, the adaptation value being a function of both the component estimates and the frequency deviation estimates to produce an intermediate set of frequency estimates, and using the frequency deviation estimates and previous frequency deviation estimates to produce an estimate of chirp for each sinusoidal component, and for each sinusoidal component combine the frequency deviation estimate and the estimate of chirp to produce a new frequency estimate.

In some embodiments, the component generator(s) convert the new set of frequency estimates to new estimated complex sinusoidal components by combining previous estimated complex sinusoidal component estimates with the new frequency estimates.

In some embodiments, a computer in combination with a computer readable medium compatible with the computer are provided which are cooperatively adapted to implement any of the above methods.

### BRIEF DESCRIPTION OF THE DRAWINGS

Preferred embodiments of the invention will now be described in greater detail with reference to the accompanying diagrams, in which:

FIG. 1 is a block diagram of an apparatus for the adaptive estimation and tracking of a multi-component sinusoidal real-valued observed signal provided by an embodiment of the invention;

FIG. 2 is a flow chart of a method provided by an embodiment of the invention for the adaptive estimation and tracking of a multi-component sinusoidal real-valued observed signal;

FIG. 3A is a block diagram of a first Component Extraction Filter (CEF) usable in the apparatus of FIG. 1;

FIG. 3B is a block diagram of a second CEF usable in the apparatus of FIG. 1;

FIG. 4A is a block diagram of a first Frequency Deviation Filter (FDF) usable in the apparatus of FIG. 1;

FIG. 4B is a block diagram of a second FDF usable in the apparatus of FIG. 1;

FIG. 5 is a block diagram showing details of the CIC and CEEs of FIG. 1;

FIG. 6 is a flow chart of a method for dynamically detecting and updating the number of prominent sinusoidal components to be tracked in the real-valued observed signal;

FIG. 7 is a block diagram of a speech coder employing the adaptive estimation and tracking method of FIG. 2;

FIG. 8 is an example implementation of one of the DCOs of FIG. 1;

FIGS. 9A and 9B contain plots of frequency tracking for different SNRs for a signal with two components. Estimated frequencies (solid) and true frequencies (dotted) are superimposed on background of the spectrum of the main signal, 9A: Tracked frequencies of the first scenario for SNR=0 dB, 9B: SNR=20 dB;

FIG. 10 contains plots of estimation errors of the proposed algorithm; solid: mean squared error |xₙ−\hat{x}ₙ|² (averaged over 50 runs), dotted: sum of MSE of components |x_{1,n}−\hat{x}_{1,n}|²+|x_{2,n}−x_{2,n}−\hat{x}_{2,n}|²;

FIG. 11 contains plots of estimated amplitudes in 20 dB, using a Hamming window with a length of 129, dotted: true values, solid and dashed: estimated values;

FIG. 12 contains plots of average of squared frequency estimation error of the proposed algorithm:

$$\frac{{\vert {f}_{1} - {\hat{f}}_{1} \vert}^{2} + {\vert {f}_{2} - {\hat{f}}_{2} \vert}^{2}}{2}$$

(averaged over 50 runs). Solid: one iteration per time instance with μ=10⁻⁴, Dashed: two iterations per time instance μ₁=10⁻⁴ and μ₂=5×10⁻⁵; and

FIGS. 13A and 13B contain plots of results of decomposing a segment of speech to four components using a μ sample length Hamming window, two iteration and different p for the components, 13A: Tracked frequencies on background of the spectrogram of the main speech, 13B: Spectrogram of the constructed signal.

### DETAILED DESCRIPTION OF THE INVENTION

The problem to be solved can be conceptualized in a discrete time mathematical model. In such a model, the signal to be examined can be considered a real-valued observed signal xₙ having L sinusoidal AM-FM components and corrupted by additive white noise. The real-valued observed signal xₙ consists of a sequence of real-valued samples of a multi-component real-valued signal. The samples are obtained by sampling with a sampling period of T and sampling frequency fₛ=1/T Hz. The real-valued observed signal can be represented mathematically as follows:

$${x}_{n} = {\sum }_{l = 1}^{L} Re ( {a}_{l} {ⅇ}^{j {ω}_{l} n} ) + {N}_{n} ; n ∈ Z \qquad ( 1 )$$

where Nₙε [symbol] is a real additive white noise sample, the complex signal a₁=|a₁6|e^{jφsi 1}ε [symbol] represents the amplitude and phase of the l^{th} component to be estimated, and ωₗε[−π,π] is the frequency (radian/sample) of the l^{th} component to be estimated. Re(.) denotes the real part of a complex number. In equation (1), it is noted that when changing the pair (ζ₁, a₁) to (−ω₁, aₗ*), where (.)* is the complex conjugate operator, the observed signal is unchanged. Thus, the sign of the frequency is not identifiable. Because of this, it can be assumed that ωₗε[0,π], and if the method used for estimation results in a negative value for the radian frequency ωₗ the pair (ωₗ, aₗ) can be changed to (−ωₗ, aₗ*) without a loss of any information. The relationship between ωₗ and the real continuous frequency fₛ is given by

$${f}_{l} = \frac{{ω}_{l}}{2 π} {f}_{s} .$$

The problem that is addressed here is to estimate the complex amplitude (i.e. amplitude and phase) and the frequency of all prominent sinusoidal components of such a signal.

It is noted that an embodiment of the invention also provides a similar but simpler solution for the case of complex observed signals, where

$${x}_{n} = {\sum }_{l = 1}^{L} {a}_{l} {ⅇ}^{j {ω}_{l} n} + {N}_{n} ∈ C .$$

The solution for the complex case is a simplified version of the real case solution, since in the complex case the quadrature components of the signal are also observed.

It is assumed that the amplitudes, the phases and the frequencies of the prominent sinusoidal components are very slowly time-varying or equivalently they are assumed to be band limited and smooth signals. Furthermore, it is assumed that each of the prominent sinusoidal components may disappear or appear, but does so in such a manner that the number of prominent sinusoidal components rarely changes. It is also assumed that the number of prominent sinusoidal components is known initially. The method may still work should one or more of these assumptions fail.

A likelihood function can be evaluated which represents the amount of information about the received (observed) signal that is available to the receiver. Evaluation of the likelihood function can provide an estimation of the unknown parameters. If it is assumed that Nₙ is a zero-mean white Gaussian random process with variance σ_{N}²(n), the log-likelihood function at time n of the observed xₙ can be expressed as follows:

$$L ( {x}_{n} \vert {\{ {a}_{n} ( n ) , {ω}_{l} ( n ) , {σ}_{N}^{2} ( n ) \}}_{l = 1}^{L} ) = - \frac{1}{2} log ( 2 π {σ}_{N}^{2} ) - \frac{{\vert {x}_{n} - {\sum }_{l = 1}^{L} Re ( {a}_{l} {ⅇ}^{j {ω}_{l} n} ) \vert}^{2}}{2 {σ}_{N}^{2}} \qquad ( 2 )$$

It is noted that within a stationary environment the maximization of the above likelihood function over a rectangular window (e.g. by expectation maximization method) could provide an appropriate estimate for the characteristic parameters of each of the prominent sinusoids contained in the observed real-valued signal. However, this approach requires a large amount of computation and also suffers from the problem of local optima which can result in inaccurate results.

Embodiments of the invention provide a method and system for evaluating the likelihood function that is computationally feasible and provides accurate estimates for the characteristic parameters of each of the prominent sinusoids contained in the observed real-valued signal.

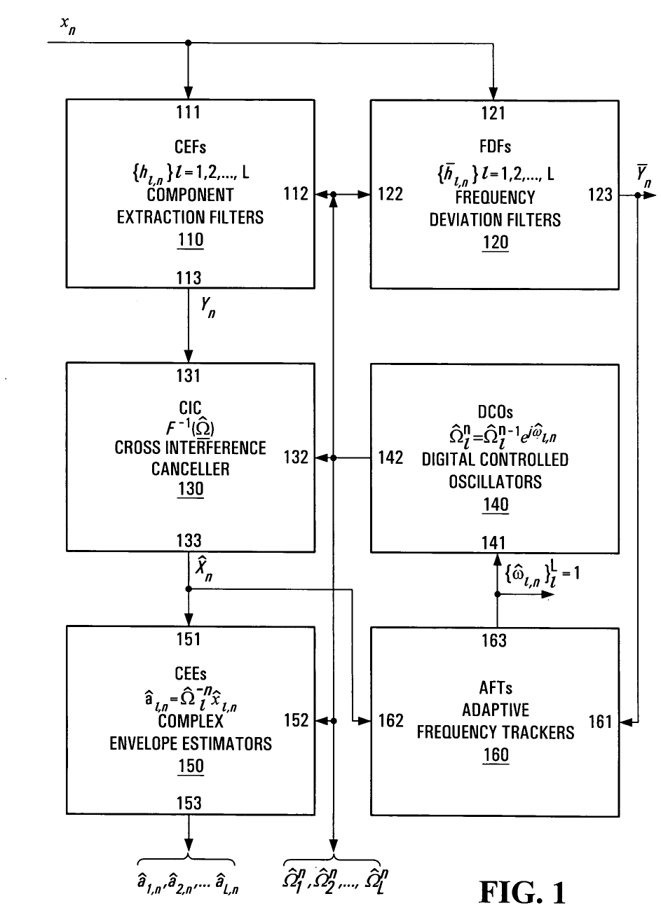

Referring now to FIG. 1, shown is a block diagram of an apparatus provided by an embodiment of the invention for the adaptive estimation and tracking of a multi-component real-valued observed signal xₙ. It is noted that in what follows, two different indices for time are used. The index “n” is used to refer to the processing performed by the method at current time n. The index “i” is a dummy variable used to refer to the observed signal at times other than the current time n. Typically, the processing at time n uses multiple different observed signals xᵢ.

A first block of the apparatus, shown in FIG. 1, is a set of Component Extraction Filters (CEFs) 110. There is one CEF for each prominent sinusoidal component being tracked. It is assumed there are L such components where L≧1. The CEFs 110 have a first input 111 and a second input 112. The first input 111 accepts the real-valued observed signal xₙ, while the second input 112 accepts a set of estimated complex sinusoidal components {\hat{Ω}ᵢⁿ}l=1, . . . , L corresponding to the prominent frequency components in the real-valued observed signal xᵢ being tracked. The CEFs 110 also have an output 113 from which they deliver a set of component estimates Yₙ made up of estimates of the prominent signal components of the real-valued observed signal xₙ. Contained within CEFs 110 are a number of filters, preferably band pass filters, each of which is tuned to a respective frequency corresponding to one of the prominent signal components of the real-valued observed signal xₙ. More specifically, in one embodiment at time n these are L band pass filters having impulse responses {h_{l,n}l=}1,2, . . . L. These band pass filters are described in further detail below.

A second block of the apparatus is a Cross-Interference Canceller (CIC) 130. The CIC 130 has a first input 131 and a second input 132. The first input 131 accepts the set of component estimates Yₙ, while the second input 132 accepts the set of estimated complex sinusoidal components {\hat{Ω}ₗⁿ}. The CIC 130 also has an output 133 from which it delivers a set of cross-interference cancelled component estimates \hat{X}ₙ of the prominent signal components of the real-valued observed signal xₙ.

A third block of the apparatus is a set of Complex Envelope Estimators (CEEs) 150. The CEEs 150 have a first input 151 and a second input 152. The first input 151 accepts the set of cross-interference cancelled signal component estimates \hat{X}ₙ, while the second input 152 accepts the set of estimated complex sinusoidal components {\hat{Ω}ₗⁿ}. The CEEs 150 also have an output 153 from which they deliver a set of complex amplitude estimates {â_{l,n}}. The CEEs 150 are made up of a number of signal multipliers, each of which is usable for a respective frequency corresponding to one of the prominent signal components of the real-valued observed signal xₙ.

A fourth block of the apparatus is a set of Frequency Deviation Filters (FDFs) 120. The FDFs 120 have a first input 121 and a second input 122. The first input 121 accepts the real-valued observed signal xₙ, while the second input 122 accepts the set of estimated complex sinusoidal components The FDFs 120 also have an output 123 from which they deliver a set of frequency deviation estimates \overline{Y}ₙ each a measure of a frequency deviation of a prominent signal component of the real-valued observed signal xₙ. The FDFs 120 consist of a set of L filters, each of which is tuned to a unique frequency corresponding to one of the prominent signal components of the real-valued observed signal xₙ. The filters have impulse responses {\overline{h}_{l,n}}l=1,2, . . . , L.

A fifth block of the apparatus is a set of Digital Controlled Oscillators (DCOs) 140. The DCOs 140 have an input 141 and an output 142. The input 141 accepts a set of frequency estimates {\hat{ω}_{l,n}}ₗ₌₁^{L} corresponding to the frequencies of prominent frequency components contained in up the real-valued observed signal xₙ. The output of the DCOs 140 available at the output 142 is a new set of estimated complex sinusoidal components {\hat{Ω}ₗⁿ} produced by combining the previous estimated complex sinusoidal components {\hat{Ω}ₗⁿ⁻¹} with the frequency estimates {\hat{ω}_{l,n}}.

A sixth and last block of the apparatus that is shown in FIG. 1 is a set of Adaptive Frequency Trackers (AFTs) 160. The AFTs 160 have a first input 161 and a second input 162. The first input 161 accepts the set of frequency deviation estimates \overline{Y}ₙ, while the second input 162 accepts the set of cross-interference cancelled component estimates \hat{X}ₙ. The AFTs 160 also have an output 163 from which they deliver the set of frequency estimates {\hat{ω}_{l,n}}.

It is noted for the single component case, only one CEF, CEE, FDF, DCO ad AFT are required and there is a single CIC so long as there are two or more components, no CIC being required for the single component case.

In operation, the real-valued observed signal xₙ is simultaneously fed to the CEFs 110 and the FDFs 120 via inputs 111 and 121 respectively. The adaptive joint estimation and tracking method provided by the invention is recursive, and the method may equivalently start at either the CEFs 110 or the FDFs 120. In alternate half-iterations of the method, either the complex amplitude estimates {â_{l,n}} are updated as a function of the observed signal xₙ and previous estimated complex sinusoidal components {\hat{Ω}ₗⁿ} or the estimated complex sinusoidal components {\hat{Ω}ₗⁿ} and the frequency estimates {\hat{ω}_{l,n}} are updated as a function of the observed signal xₙ and previous cross-interference cancelled estimates \hat{X}ₙ. The CEFs 110 and the FDFs 120 generate values for the component estimates Yₙ and frequency deviation estimates Ŷₙ respectively. Both the CEFs 110 and the FDFs 120 are initialized with estimates of the estimated complex sinusoidal components, corresponding to each of the prominent sinusoidal components contained in the real-valued observed signal xₙ. Furthermore, both the CEFs 110 and the FDFs 120 indirectly supply the DCOs 140 a feedback signal that allows the DCOs 140 to update the frequency estimates.

The CEFs 110, CIC 130 and CEEs 150 collectively process the observed signal xₙ to produce complex amplitude estimates â_{l,n} of the prominent sinusoidal components. Each of the filters in CEFs 110 filters the observed signal xₙ to produce a respective initial estimate Yₙ of each frequency component. The filters are tuned to look at frequencies specified by the estimated complex sinusoidal components {\hat{Ω}ₗⁿ}. The CIC 130 accepts the component estimates Yₙ generated by the CEFs 110 and the estimated complex sinusoidal components generated by the DCOs 140. The CIC 130 can be basically described as a matrix processor that combines the estimated complex sinusoidal components with the component estimates Yₙ to produce the cross-interference cancelled component estimates \hat{X}ₙ. The mathematical details of this block will be given in detail in what follows.

The CEEs 150 operate by multiplying the estimated complex sinusoidal components and the corresponding cross-interference cancelled component estimates \hat{X}ₙ to produce the set of complex amplitude estimates, each complex amplitude estimate corresponding to a respective prominent sinusoidal component contained in the observed signal xₙ.

The FDFs 120, DCOs 140 and AFTs 160 collectively process the observed signal xₙ to produce the estimated complex sinusoidal component {\hat{Ω}ₗⁿ} and frequency estimates {\hat{ω}_{l,n}}. The FDFs 120 generate estimates of the prominent sinusoidal components frequency deviations from the real-valued observed signal and previous estimates of the frequencies present in the real-valued observed signal xₙ. The filters in the FDFs 120 filter the observed signal to produce the set of estimates Ŷₙ of deviations in the modulated frequency of the prominent sinusoidal components from the previous estimates. The FDFs 120 pass the frequency deviation estimates Ŷₙ they have generated to the AFTs 160 as shown in FIG. 1. The AFTs 160 use the frequency deviation estimates Ŷₙ from the FDFs 120 and the cross-interference cancelled component estimates \hat{X}ₙ from the CIC 130 to generate the set of frequencies {\hat{ω}_{l,n}} corresponding to the respective components contained the real-valued observed signal.

The frequencies {\hat{ω}_{l,n}} generated by the AFTs 160 are output by the method as the new set of frequency estimates. They are also passed to the DCOs 140, which contain recursive complex sinusoidal signal generators that modulate the frequency estimates by combining them with previous estimates to produce estimated complex sinusoidal components and in so doing reduces the effect of noise in the frequency estimates. Filtering the frequency estimates in this way minimizes the amount of computational error propagated by erroneous frequency estimation. As previously indicated the DCOs 140 then send the new estimated complex sinusoidal components {\hat{Ω}ᵢⁿ} to the CEFs 110, the FDFs 120, the CIC 130 and the CEEs 150, so that the next iteration of processing can proceed.

The mathematics behind the approach embodied in FIG. 1 will now be presented. The adaptive estimation and tracking method provided by an embodiment of the invention is obtained by maximizing a weighted average of equation (2), the likelihood equation given above. The weighted-average of equation (2) is taken over a finite amount of time, or rather within a window in time. A recursive adaptive filter with a low order of computational complexity is employed to achieve this.

By appropriately selecting the averaging window the problem of converging on an erroneous local optima (e.g. what is known as a false-lock in a PLL) can be overcome, with the additional benefit of controlling the noise limiting and tracking behavior of the adaptive estimation and tracking method. In order to estimate the parameters characterizing prominent sinusoidal components comprising the real-valued observed signal xₙ at a time n, in a preferred embodiment the following parametric windowed (weighted) log-likelihood function is maximized:

$$L ( n ) = {\sum }_{i = - ∞}^{+ ∞} {W}_{n - i} L ( {x}_{i} \vert {\{ {a}_{l} ( i ) , {ω}_{l} ( i ) , {σ}_{N}^{2} ( i ) \}}_{l = 1}^{L} ) \qquad ( 3 )$$

In equation (3) Wₖ is a window function described in detail below, where k is an index for the window function which is set relative to n, i.

This approach will be referred to herein as the Maximum Weighted Likelihood (MWL) approach. Despite being presented within a system that assumes a stationary environment, it should be noted that this approach is also suitable for non-stationary and adaptive parameter estimation.

Furthermore, the weighted log-likelihood function can be employed, and adapted for implementation using the apparatus of FIG. 1, by defining the impulse response {h_{l,n}} and {\overline{h}_{l,n}} as described below. In another embodiment, the structure of FIG. 1 is provided with no specific constraints on the impulse responses {h_{l,n}} and {\overline{h}_{l,n}}.

Referring to equation (3), the value wₙ₋ᵢ is the weight of the information received at time n−i in order to estimate the unknown parameters at time n. In some embodiments, the window function, wₖ, is selected to satisfy one or more of the following conditions:

1. The window is normalized (i.e. Σₖwₖ=1).

2. The window is centered at zero (i.e. ΣkWₖ=0).

3. The causality of the adaptive estimation and tracking method relies on ∀ₖ≦D [symbol] wₖ=0, where D denotes an acceptable delay for the estimated parameters characterizing the prominent sinusoidal components comprising the real-valued observed signal xₙ.

4. The condition for L(n) to yield a positive integration from the information gathered at different time instances is that: Wₖ≧0.

The first condition is not absolutely necessary. It has been included because it simplifies the discussion in regard to the adaptive estimation and tracking method being described. The second condition could also be violated, in such a case, the value of

$${\sum }_{k = - ∞}^{+ ∞} k {W}_{k}$$

represents the delay lag of the estimation. Again the second condition has been included because it simplifies the upcoming description of the adaptive estimation and tracking method. More generally, if one or more of the conditions are not satisfied, the performance might degrade depending on the situation.

Considering more carefully the above conditions, it can be observed that if wₖ is considered to be the unit impulse response of a linear time-invariant filter, this filter is strictly a lowpass filter having its maximum frequency domain gain for the DC component.

Additionally, if the window weights wₖ are all non-negative, L(n) represents a measure of the received information about the parameters in the neighborhood of time n. This window will determine the resolution of the frequency estimation and the extracting filters for the complex amplitude aₗ.

The maximization of the criterion in equation (3) does not resolve the problem because the number of unknown parameters in equation (3) is more than the number of parameters obtained by observation within the window. So as an approximation, it is assumed that the unknown parameters are approximately constant across the course of the window and this approximation allows the likelihood function to be simplified. Consequently, the following simplified likelihood function is maximized in place of equation (3):

$$\begin{matrix}\hat{L} ( n ) = {\sum }_{i = - ∞}^{+ ∞} {w}_{n - i} L ( {x}_{i} \vert {\{ {a}_{l} ( n ) , {ω}_{l} ( n ) , {σ}_{N}^{2} ( n ) \}}_{l = 1}^{L} ) \approx L ( n ) \\ = - \frac{1}{2} log ( 2 π {σ}_{N}^{2} ( n ) ) - \frac{{\sum }_{i = - ∞}^{+ ∞} {\vert {x}_{i} - {\sum }_{l = 1}^{L} Re ( {a}_{l} {ⅇ}^{j {ω}_{l} i} ) \vert}^{2} {w}_{n - i}}{{σ}_{N}^{2} ( n )}\end{matrix} \qquad ( 4 )$$

Due to the approximation made above an inherent approximation error is introduced resulting from ignoring information about the real-valued observed signal. The approximation error reduces as the variation of the observed parameters reduces as caused by shortening the window length. Yet with a longer window length a longer duration of the observed signal can be used. This has the effect of increasing the estimation accuracy as long as the variance of the observed parameters is sufficiently small. However, it is not always the case that the variances of the parameters characterizing the prominent sinusoidal components of the real-valued observed signal will be sufficiently small and such circumstances can not be guaranteed to occur in practical applications of the invention. This shows a trade-off to be considered when choosing the duration of the time domain window. The length of the time domain window is preferably chosen so that the effects of the varying parameters characterizing the observed (received) signal are balanced against the requirement to observe an adequate portion of the observed signal. Thus, it is clear that a shorter time domain window length is preferable in practical embodiments of the invention. The exact length of the time domain window may be determined for a particular application by empirical methods.

Maximizing \hat{L}(n) with respect to Γ_{N}²(n), the result is the following equation that approximates the variance:

$${\hat{σ}}_{N}^{2} ( n ) = {\sum }_{i = - ∞}^{+ ∞} {\vert {x}_{i} - {\sum }_{l = 1}^{L} Re ( {a}_{l} {ⅇ}^{{jω}_{l} i} ) \vert}^{2} {w}_{n - i} \qquad ( 5 )$$

Next, the value of \hat{σ}_{N}²(n) is substituted from equation (5) into equation (4) and then \hat{L} is maximized with respect to other parameters. The result of this operation is another estimate of the likelihood function as follows:

$$\hat{L} ( n ) = - \frac{1}{2} log ( 2 e π {\sum }_{i = - ∞}^{+ ∞} {\vert {x}_{i} - {\sum }_{l = 1}^{L} Re ( {a}_{l} {ⅇ}^{j {ω}_{l} i} ) \vert}^{2} {w}_{n - i} ) \qquad ( 6 )$$

Maximizing equation (6) yields to minimization of the following Weighted-Least-Square (WLS) criterion for estimation of amplitude and frequency at time n:

$$J ( n ) = {\sum }_{i = - ∞}^{+ ∞} {\vert {x}_{n - i} - {\sum }_{l = 1}^{L} Re ( {a}_{l} {ⅇ}^{{jω}_{l} ( n - i )} ) \vert}^{2} {w}_{i} \qquad ( 7 )$$

The window wₖ has a direct impact on the lock-in range of the adaptive estimation and tracking method, wherein the main-lobe width of the Fourier spectrum of wₖ defines the lock-in range. In general the lock-in range of a method is the maximum initial frequency deviation that can be tolerated by the method such that the method can acquire and begin to track the input frequency.

Throughout the rest of this disclosure; the following notations and definitions are adopted in order to provide all of the mathematical details of the present invention:

the vector of the complex modulated amplitudes:

$$X ≡ {[ {a}_{l} {ⅇ}^{{jω}_{l} n} , ⋯ , {a}_{L} {ⅇ}^{{jω}_{L} n} ]}^{T} \\ = [ {x}_{l , n} , ⋯ , {x}_{L , n} ] = {X}_{r , n} + {jX}_{i , n}$$

the estimation of the clean signal:

$${\hat{x}}_{n} = {\sum }_{l = 1}^{L} Re ( {\hat{x}}_{l , n} )$$

the estimation error:

eₙ≡xₙ−\hat{x}ₙ

the derivative of a real-valued function f(v) with respect to a complex variable v:

$$\frac{\partial f ( v )}{\partial v} ≡ \frac{1}{2} \frac{\partial f ( v )}{\partial Re ( v )} - \frac{j}{2} \frac{\partial f ( v )}{\partial lm ( v )}$$

A window: wᵢ≧0 and W(1)=1:

$$W ( z ) = {\sum }_{i = - ∞}^{∞} {w}_{i} {z}^{- i}$$

$$\overline{W} ( z ) = {\sum }_{i = - ∞}^{∞} {iw}_{i} {z}^{- i} = - z \frac{ⅆ}{ⅆ z} W ( z ) \overline{W} ( 1 ) = 0$$

Ω≡[Ω₁, . . . , Ω_{L}]^{T}≡[e^{jω}^{ₗ}, . . . , e^{jω}^{_{L}}]⁵,

To begin, a detailed derivation of how the complex envelope estimates {â_{l,n}} are computed by blocks 110, 130, 150 of FIG. 1 will be presented.

To maximize J(n) set

$$\frac{\partial J ( n )}{\partial {a}_{l}} = 0$$

for l=1, . . . , L. Thus,

$$\begin{matrix}\frac{\partial J ( n )}{\partial {a}_{l}} = {\sum }_{i = - ∞}^{∞} ( {\sum }_{p = 1}^{L} Re ( {a}_{p} {ⅇ}^{j {ω}_{p} ( n - 1 )} ) - {x}_{n - i} ) {ⅇ}^{j ω l ( n - i )} {W}_{i} \\ = {\sum }_{i = - ∞}^{∞} {\sum }_{p = 1}^{L} Re ( {a}_{p} {ⅇ}^{j {ω}_{p} ( n - i )} ) {ⅇ}^{j {ω}_{l} ( n - i )} {W}_{i} - \\ {\sum }_{i = - ∞}^{∞} {x}_{n - i} {ⅇ}^{j {ω}_{l} ( n - i )} {W}_{i} \\ {\sum }_{i = - ∞}^{∞} {\sum }_{p = 1}^{L} \frac{{a}_{p} {ⅇ}^{j {ω}_{p} ( n - i )} + {a}_{p}^{*} {ⅇ}^{- j {ω}_{p} ( n - i )}}{2} {ⅇ}^{j {ω}_{l} ( n - i )} {W}_{i} - \\ {ⅇ}^{j {ω}_{l} n} {\sum }_{i = - ∞}^{∞} {x}_{n - i} {ⅇ}^{- j {ω}_{l} i} {W}_{i} .\end{matrix} \qquad ( 8 )$$

Given the values of the frequencies {ωₗ}ₗ₌₁^{L}, the above system (equation (8)) is solved to provide estimates of the complex amplitudes {aₚ}ₚ₌₁^{L} for each of the prominent sinusoidal components. To simplify the solution of the above system, it is useful to define the following set of linear filters:

$${h}_{l , n} ≡ {ⅇ}^{j {ω}_{l} n} {W}_{n} \\ {H}_{l} ( z ) ≡ {\sum }_{i = - ∞}^{∞} {h}_{l , n} {z}^{- 1} = W ( {ⅇ}^{j {ω}_{l}} z ) = W ( {Ω}_{l} z ) . \qquad ( 9 )$$

Component estimate y_{l,n} (collectively the vector Yₙ of FIG. 1) can be computed according to:

$${y}_{l , n} ≡ {x}_{n} ⊗ {h}_{l , n} = {\sum }_{i = - ∞}^{∞} {x}_{n - 1} {ⅇ}^{- j {ω}_{l} i} {W}_{i} \\ = {ⅇ}^{j {ω}_{l} n} {\sum }_{i = - ∞}^{∞} {x}_{n - 1} {ⅇ}^{j {ω}_{l} ( n - i )} {W}_{i} = {ⅇ}^{- j {ω}_{l} n} [ ( {ⅇ}^{j {ω}_{l} n} {x}_{n} ) ⊗ {W}_{n} ] \qquad ( 10 )$$

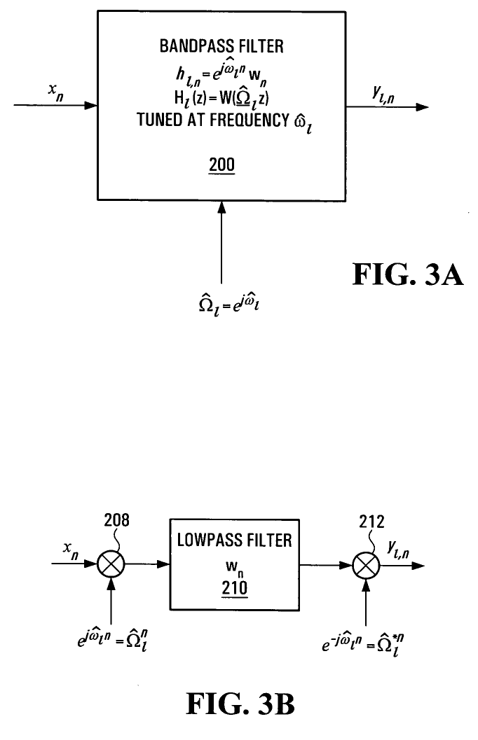

Referring to FIG. 3A and the filters given by equation (9), it can be seen that y_{l,n} can be computed as the output of a linear bandpass filter 200 that is tuned to the estimated centre frequency \hat{ω}ₗ, for the l^{th} prominent sinusoidal component of the real-valued observed signal. The CEFs 110 of FIG. 1 include one such band pass filter 200 for each component. FIG. 3B shows an equivalent lowpass filter implementation of the filter shown in FIG. 3A. A multiplier 208 multiplies the input xₙ by e^{j\hat{ω}}ₗⁿ. The result is lowpass filtered with a lowpass filter 210 having an impulse response equal to the weighting function wₖ. The output is multiplied by e^{-j\hat{ω}}ₗⁿ with multiplier 212. Both filters, shown in FIGS. 3A and 3B, attenuate all components except the corresponding component and the corresponding component appears at the output with unity gain. In other words the filter is substantially dimensionless for a particular component (Hₗ(Ωₗ)=1) when the estimated frequency is accurate. In this manner, it is easy to understand how the adaptive estimation and tracking method operates to reject additive noise. The filter Hₗ(z) should be designed to pass through the l^{th} component. The bandwidth of Hₗ(z) equals the bandwidth of W and should be more than the bandwidth of the amplitudes.

Each filter is only adjusted by one parameter, namely the previous estimated complex sinusoidal component, and the output of each filter will contain some interference from other components arising from non-zero gain in the stop band of each filter. These cross-interferences can be removed by summarizing (8) in the following equation:

$$\begin{matrix}\frac{\partial J ( n )}{\partial {a}_{l}} = {\sum }_{p = 1}^{L} {\sum }_{i = - ∞}^{∞} \frac{{a}_{p} {ⅇ}^{j ( {ω}_{l} + {ω}_{p} ) ( n - i )} + {a}_{p}^{*} {ⅇ}^{j ( {ω}_{l} {ω}_{p} ) ( n - i )}}{2} {W}_{i} - \\ {ⅇ}^{j {ω}_{l} n} {y}_{l , n} \\ = {ⅇ}^{j {ω}_{l} n} ( \sum \frac{{a}_{p} {ⅇ}^{j {ω}_{p} n} W ( {ⅇ}^{j ( {ω}_{l} + {ω}_{p} )} ) + \\ {a}_{p}^{*} {ⅇ}^{- j {ω}_{p} n} W ( {ⅇ}^{j ( {ω}_{l} - {ω}_{p} )} )}{2} - {y}_{l , n} ) .\end{matrix} \qquad \text{(11)}$$

From

$$\frac{\partial J ( n )}{\partial {a}_{l}} = 0 ,$$

the following is derived

$$2 {y}_{l , n} = {\sum }_{p = 1}^{L} {a}_{p} {ⅇ}^{j {ω}_{p} n} W ( {ⅇ}^{j ( {ω}_{l} + {ω}_{p} )} ) + {a}_{p}^{*} {ⅇ}^{- j {ω}_{p} n} W ( {ⅇ}^{j ( {ω}_{l} - {ω}_{p} )} ) . \qquad ( 12 )$$

To have a matrix form solution, it is useful to define the following:

$${Y}_{n} ≡ {[ 2 {y}_{l , n} , … , 2 {y}_{L , n} ]}^{T} = 2 {Y}_{r , n} + 2 {{jY}_{i , n} \\ [ W ( \underline{Ω} ) ]}_{l , p} ≡ {W ( {Ω}_{l} {Ω}_{p} ) \\ [ V ( \underline{Ω} ) ]}_{l , p} ≡ W ( {Ω}_{l} / {Ω}_{p} ) . \qquad ( 13 )$$

Note that there is no need for a computational division operation in calculation of W(Ωₗ/Ωₚ) as W(Ωₗ/Ωₚ)=W(ΩₗΩₚ*). Thus from equation (12) and the definitions given in (13), the linear system can be solved by solving the following complex set of equations:

Yₙ=W(Ω)Xₙ+V(Ω)Xₙ* (14)

where (.)* denotes the conjugate operator. Expanding the L-dimensional complex-valued system of (14) into a 2L-dimensional real-valued system, the following is the result:

$$[ \begin{matrix}{Y}_{r , n} \\ {Y}_{i , n}\end{matrix} ] = [ \begin{matrix}Re \{ W ( \underline{Ω} ) + V ( \underline{Ω} ) \} & - lm \{ W ( \underline{Ω} ) - V ( \underline{Ω} ) \} \\ lm \{ W ( \underline{Ω} ) + V ( \underline{Ω} ) \} & Re \{ W ( \underline{Ω} ) - V ( \underline{Ω} ) \}\end{matrix} ] [ \begin{matrix}{X}_{r , n} \\ {X}_{i , n}\end{matrix} ] = F ( \underline{Ω} ) [ \begin{matrix}{X}_{r , n} \\ {X}_{i , n}\end{matrix} ] . \qquad ( 15 )$$

When the frequencies of the prominent sinusoidal components are far enough apart F(Ω) will not be ill conditioned.

Thus, by applying the inverse of F(Ω) the following solution determines the cross-interference cancelled component estimates

$$[ \begin{matrix}{\hat{X}}_{r , n} \\ {\hat{X}}_{i , n}\end{matrix} ] = {F}^{- 1} ( \underline{\hat{Ω}} ) [ \begin{matrix}{Y}_{r , n} \\ {Y}_{i , n}\end{matrix} ] \qquad ( 16 )$$

F⁻¹(\hat{Ω}) removes the cross-interference of adjacent prominent sinusoidal components and will be referred to as the “cross-interference cancelled matrix”, or CIC matrix. Using (16), the cross-interference cancelled modulated component estimates (i.e. the vector \hat{X}ₙ=\hat{X}_{r,n}+j\hat{X}_{i,n}) are obtained. As J(n) is a quadratic function of the amplitudes the above solution is the optimum.

The complex amplitudes of the prominent sinusoidal components are then estimated by:

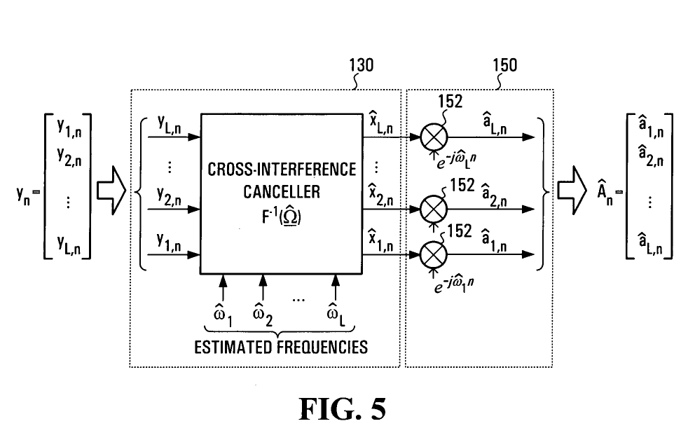

Âₙ=[â_{l,n},â_{2,n}, . . . ,â_{L,n}]^{T}=[e^{-j\hat{ω}}₁ⁿ, . . . , e^{-j\hat{ω}}₂ⁿ, . . . e^{-j\hat{ω}}_{L}ⁿ]^{T}*\hat{X}ₙ (17)

where the symbol * denotes element-wise multiplication of the elements of two vectors. Referring now to FIG. 1, the CIC 130 operates to multiply the components output by the CEFs 110 by the CIC matrix to produce the cross-interference cancelled components \hat{X}ₙ. The CEEs 150 calculate equation (17) and output the complex envelope estimates â_{l,n}. The operation of the CIC 130 and CEEs 150 together is shown in further detail in FIG. 5, which shows the component estimates before CIC Yₙ={Y_{l,n}} input to a cross-interference cancellation matrix multiplication which multiplies Yₙ by F⁻¹(\hat{Ω}) The output \hat{X}ₙ={\hat{x}_{l,n}} is multiplied by the set of e^{-j\hat{ω}}ₗⁿ in the multipliers 152 of the CEEs 150 to produce the complex amplitude estimates.

The optimization of J(n) to track and to estimate the frequencies of the prominent sinusoidal components involves non-linear time varying filtering. According to a preferred embodiment of the invention, an adaptive method for the estimation and tracking of frequencies and amplitudes is provided.

It is assumed that an accurate initial value is provided for the frequency of each prominent sinusoidal component. This initial value can be obtained from the previous iteration of the method, by another method or by a simple initialization procedure. Then, once \hat{X}ₙ is obtained from (16) it is substituted into J(n) as shown in the following:

$${e}_{n - i} = {x}_{n - i} - {\sum }_{l = 1}^{L} Re ( {\hat{a}}_{l} {ⅇ}^{j {\hat{ω}}_{l} ( n - i )} ) = {x}_{n - i} - {\sum }_{l = 1}^{L} Re ( {\hat{x}}_{l , n} {ⅇ}^{- j {\hat{ω}}_{l} i} ) \\ J ( n ) = {\sum }_{i = - ∞}^{∞} {\vert {x}_{n - i} - {\sum }_{l = 1}^{L} Re ( {\hat{x}}_{l , n} {ⅇ}^{- j {ω}_{l} i} ) \vert}^{2} {W}_{i} \qquad ( 18 )$$

Following the above substitution yielding equation (18) J(n) is minimized with respect to the unknown frequencies, each of the unknown frequencies corresponding to each of the prominent sinusoidal components. Once this is completed, an iterative approach may be used to find \hat{X}ₙ again and so on until the desired level of accuracy is obtained. However, for this example, only a single iteration for each time step n will be demonstrated. The adaptive methods work with only one iteration. Increasing the number of iterations provides some improvement at the expense of increased computational complexity. The frequency estimates obtained by the adaptive method for the estimation and tracking method is then used as the initial value (estimate) for the next time iteration n+1.

To optimize, one may ignore the dependency between \hat{X}ₙ and Ω and compute

$$\frac{\partial J ( n )}{\partial \underline{Ω}}$$

as follows

$$\frac{\partial J ( n )}{\partial {ω}_{l}} = - {\sum }_{i = - ∞}^{∞} ( {x}_{n - i} - {\sum }_{p = 1}^{L} Re ( {\hat{x}}_{p , n} {ⅇ}^{- j {\hat{ω}}_{p} i} ) ) lm ( {\hat{x}}_{l , n} {ⅇ}^{- j {\hat{ω}}_{l} i} {W}_{i} ) \qquad ( 19 )$$

Defining

$$\frac{\partial J ( n )}{\partial {ω}_{l}}$$

to be equal to Im(Δ_{l,n}), Δ_{l,n} equals

$${Δ}_{l , n} = - {\sum }_{i = - ∞}^{∞} ( {x}_{n - i} - {\sum }_{p = 1}^{L} Re ( {\hat{x}}_{l , n} {ⅇ}^{- j {\hat{ω}}_{l} i} ) ) {\hat{x}}_{l , n} {ⅇ}^{- j {\hat{ω}}_{l} i} {iW}_{i} \\ = - {\hat{x}}_{l , n} {\sum }_{i = - ∞}^{∞} ( {x}_{n - i} {ⅇ}^{- j {\hat{ω}}_{l} i} {iW}_{i} - {\sum }_{p = 1}^{L} Re ( {\hat{x}}_{p , n} {ⅇ}^{- j {\hat{ω}}_{p} i} ) {ⅇ}^{- j {\hat{ω}}_{l} i} {iW}_{i} ) \qquad ( 20 )$$

To simplify the realization of the above system, and to convert it to matrix form, a set of linear filters is defined similar to those that were used to derive estimates for the complex amplitudes of the prominent sinusoidal components.

$${\overline{h}}_{l , n} ≡ {ⅇ}^{- j {ω}_{l} n} {nW}_{n} , \\ {\overline{H}}_{l} ( z ) ≡ {\sum }_{l = - ∞}^{∞} {\overline{h}}_{l , n} {z}^{- 1} = \overline{W} ( {ⅇ}^{j {\hat{ω}}_{l}} z ) = \overline{W} ( {Ω}_{l} z ) . \qquad ( 21 )$$

Estimates of the frequency deviations \overline{Y}_{l,n} (collectively the vector \overline{Y}ₙ of FIG. 1) can be computed according to:

$${\overline{y}}_{l , n} ≡ {x}_{n} ⊗ {\overline{h}}_{l , n} = \sum {x}_{n - i} {ⅇ}^{- j {\hat{ω}}_{l} ⅈ} i {w}_{i} . \qquad ( 22 )$$

It is now useful to define the following:

$$\begin{matrix}{\overline{Y}}_{n} = {[ {\overline{y}}_{1 , n} , … , {\overline{y}}_{L , n} ]}^{T} , \\ {[ \overline{W} ( \hat{\underline{Ω}} ) ]}_{l , p} ≡ \overline{W} ( {\hat{Ω}}_{l} {\hat{Ω}}_{p} ) , \\ {[ \overline{V} ( \hat{\underline{Ω}} ) ]}_{l , p} ≡ \overline{W} ( {\hat{Ω}}_{l} / {\hat{Ω}}_{p} ) , \\ {Δ}_{n} ≡ {[ {Δ}_{1 , n} , {Δ}_{2 , n} , … , {Δ}_{L , n} ]}^{T} .\end{matrix} \qquad ( 23 )$$

Thus,

$$\begin{matrix}{Δ}_{l , n} = {\hat{x}}_{l , n} ( {\sum }_{p = 1}^{L} {\sum }_{i = - ∞}^{∞} Re ( {\hat{x}}_{p , n} {ⅇ}^{- j {\hat{ω}}_{p} ⅈ} ) {ⅇ}^{- j {\hat{ω}}_{l} ⅈ} i {w}_{i} - {\overline{y}}_{l , n} ) \\ = {\hat{x}}_{l , n} {\sum }_{p = 1}^{L} {\sum }_{i = - ∞}^{∞} \frac{1}{2} ( {\hat{x}}_{p , n} {ⅇ}^{- j {ω}_{p} ⅈ} + {\hat{x}}_{p , n}^{*} {ⅇ}^{j {ω}_{p} ⅈ} ) {ⅇ}^{- j {\hat{ω}}_{l} ⅈ} i {w}_{i} - {\hat{x}}_{l , n} {\overline{y}}_{l , n} \\ = {\hat{x}}_{l , n} [ \sum \frac{1}{2} ( {\hat{x}}_{p , n} \overline{W} ( {ⅇ}^{j ( {\hat{ω}}_{l} + {\hat{ω}}_{p} )} ) + {\hat{x}}_{p , n}^{*} \overline{W} ( {ⅇ}^{j ( {\hat{ω}}_{l} - {\hat{ω}}_{p} )} ) ) - {\overline{y}}_{l , n} ]\end{matrix} \qquad ( 24 )$$

From (23) and (24), we find

$${Δ}_{n} = {\hat{X}}_{n} ⊗ ( \frac{1}{2} ⌊ \overline{W} ( \hat{\underline{Ω}} ) {\hat{X}}_{n} + \overline{V} ( \hat{\underline{Ω}} ) {\hat{X}}_{n}^{*} ⌋ - {\overline{Y}}_{n} ) \qquad ( 25 )$$

The vector Δₙ can be computed directly using the previous estimated complex sinusoidal components {\hat{Ω}ₗⁿ}, the cross-interference cancelled component estimates \hat{X}ₙ, and the frequency deviation estimates \overline{Y}ₙ.

Different methods of applying the frequency deviation estimates to determine new frequency estimates may be applied. In one embodiment the vector Δₙ is used to produce new estimates for the frequencies. Referring to FIG. 1, the AFTs 160 compute the Δₙ from \hat{X}ₙ, Ŷₙ and the previous estimated complex sinusoidal components defined by {\hat{Ω}ₗⁿ}. The AFTs then apply the values of Δₙ to compute new frequencies. The following equation defines a simple gradient method that is preferably used in the present embodiment of the invention:

\hat{ω}_{l,n+1}=\hat{ω}_{l,n}−μlmΔ_{l,n}; l=1, . . . , L (26)

It is to be understood other methods may be used. In equation (26) μ is a very small-sized positive adaptation step that is usually a constant value, i.e. it does not vary in time. One may apply the result of (26) into (16) and vice versa recursively. However, in the simplest implementation, (16) is evaluated and then (26) is evaluated, each once at each time instant (step) n. The overall method is an adaptive method for the estimation and tracking of small frequency variations and a least square estimation of amplitude of the prominent sinusoidal components.

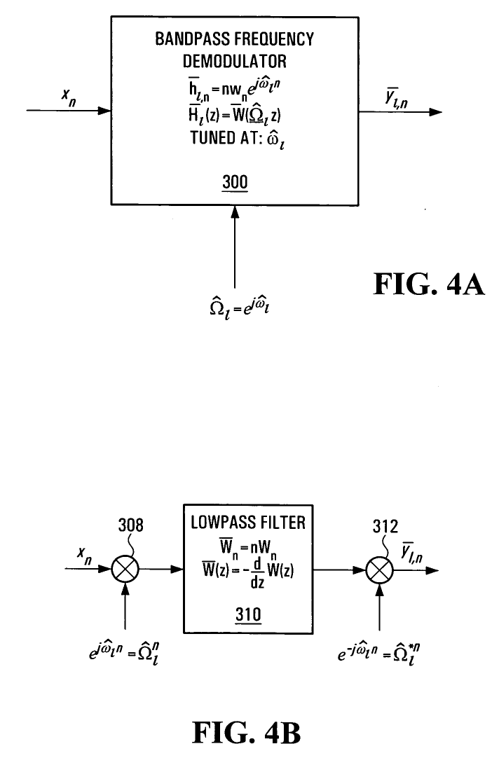

Referring to FIG. 4A and the filters defined by equation (23), in some embodiments \overline{y}_{l,n} can be implemented as the output of a linear bandpass filter 300 that is tuned to the estimated centre frequency \hat{ω}ₗ, for the l^{th} prominent sinusoidal component of the real-valued observed signal. FIG. 4B shows the substantially equivalent lowpass filter implementation 310 of the filter shown in FIG. 4A. The structure of the lowpass filter embodiment is similar to that of FIG. 3B, but with a different lowpass filter impulse response. A third alternative to FIGS. 3A, 4A and FIGS. 3B, 4B, is to implement filters in an Intermediate Frequency (IF) (for both digital and the analogue implementation described below). For analogue implementations of the algorithm the IF implementation could be advantageous.

In order to avoid computational error and to reduce the effect of noise on the generation of the estimation of the prominent sinusoidal components Ωₗⁿ=e^{jω}^{ₗ}ⁿ the DCOs 140 are used. The DCOs contain recursive complex sinusoidal signal generators which operate on previous estimated complex sinusoidal components, and the new frequency estimates \hat{ω}_{l,n} as follows:

\hat{Ω}ₗⁿ=\hat{Ω}ₗⁿ⁻¹e^{j\hat{ω}}_{l,n} (27)

The output of the DCOs 140 is the new set of estimated complex sinusoidal components.

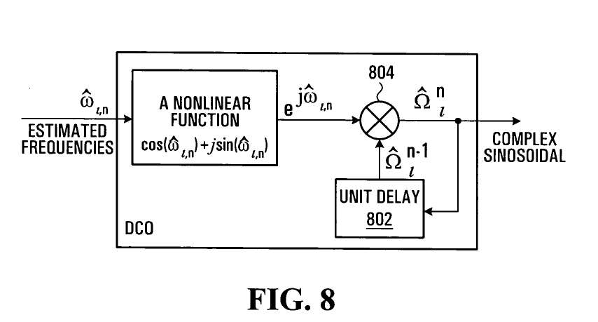

An example DCO implementation is shown in FIG. 8. The estimated frequency \hat{ω}_{l,n} is converted to a complex exponential e^{j\hat{ω}}_{l,n} by a non-linear function 800. The previous output of the DCO is \hat{Ω}ₗⁿ⁻ⁱ, and this is subject to one unit delay 802 so as to be made available at the current processing instant. The current complex sinusoidal \hat{Ω}ₗⁿ is determined by multiplying e^{j\hat{ω}}_{l,n} by \hat{Ω}ₗⁿ⁻ⁱ with multiplier 804. This structure is repeated for each prominent sinusoidal component.

It is noted that in a conventional FM radio receiver, the input signal has only one component and the amplitude is assumed to be constant. Consequently, a structure with behavior similar to a single Frequency Deviation Filter (FDF) 120 is used for demodulation of frequency. However, the demodulated signal is proportional to the deviation of its input frequency and is not exactly equal to the actual frequency. In the approach provided by the present invention, this signal is used in a feedback loop as in FIG. 1 and described by equation (22), to adaptively estimate/correct the frequency by minimizing the deviation of the observed signal from its estimate. Because of this, it is expected that the adaptive method for the estimation and tracking will provide improvement even in a FM radio.

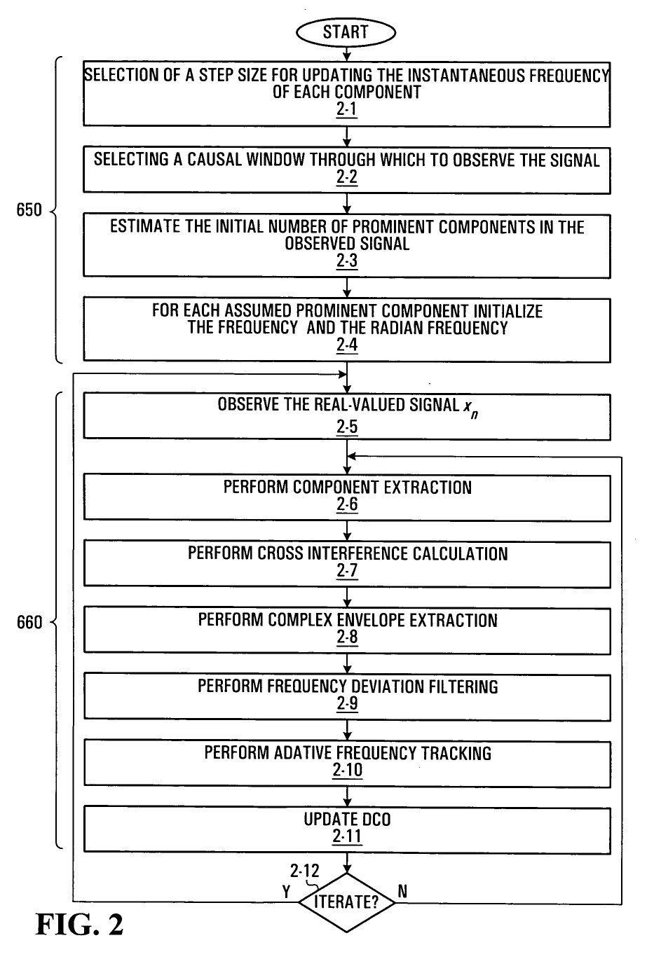

Referring now to FIG. 2, shown is a flow chart that illustrates the adaptive estimation and tracking method implemented by the functional blocks of FIG. 1. Included in the flow chart is a preferred initialization step that may be used to start the process at its very first iteration.

The adaptive estimation and tracking method has an initialization stage 650 and a steady-state operation stage 660.

The initialization stage 650 begins at step 2-1 with choosing an incremental step size p to update the instantaneous frequencies of the prominent sinusoidal components. The method continues at step 2-2 with the selection and initialization of a causal window function through which to observe the real-valued signal. The window function is chosen so that it satisfies the aforementioned conditions. An initial estimation of the number of prominent sinusoid components comprising the received signal is made in step 2-3. This is then followed by step 2-4 in which the frequencies are initialized. The first three steps of the initialization stage 2-1, 2-2 and 2-3 may be done in any order; however, step 2-4 can only be done after 2-3 has been completed.

The first step of the steady state operation 660 of the method is to observe the real-valued signal, as indicated in step 2-5 of FIG. 2. In this case it is assumed that the iterative process begins with the computation of the complex amplitudes. However, it is noted that equivalently, the process could begin with the computation of the frequency estimates. The method continues at step 2-6 with the performance of the component extraction step. At step 2-7 the cross-interference cancellation step is performed. At step 2-8, the complex envelopes are extracted. The output of step 2-8 is a new set of amplitude estimates. Next, at step 2-9 frequency deviation filtering is performed. Step 2-9 occurs on the basis of the same set of observed signals xₙ as was used in step 2-6. The method continues at step 2-10 with the performance of the adaptive frequency tracking. Finally, the iteration finishes at step 2-11 with the updating of the frequency estimates with the digital control oscillators. Depending upon whether or not the entire process is to be iterated, as determined by step 2-11, all of steps 2-6 through 2-11 can be repeated for the same set of observed signals. In the simplest implementation, only one iteration is performed. The method continues back at step 2-5 with the observation of the next real-valued signal xₙ. The updating of the complex amplitude estimates is one half-iteration, and the updating of the frequencies is another half-iteration.

Preferably the invention is further enhanced so as to be able to simultaneously detect the appearance of new prominent sinusoidal components, the presence of already identified and previously tracked prominent sinusoidal components and the disappearance of prominent sinusoidal components comprising the real-valued observed signal.

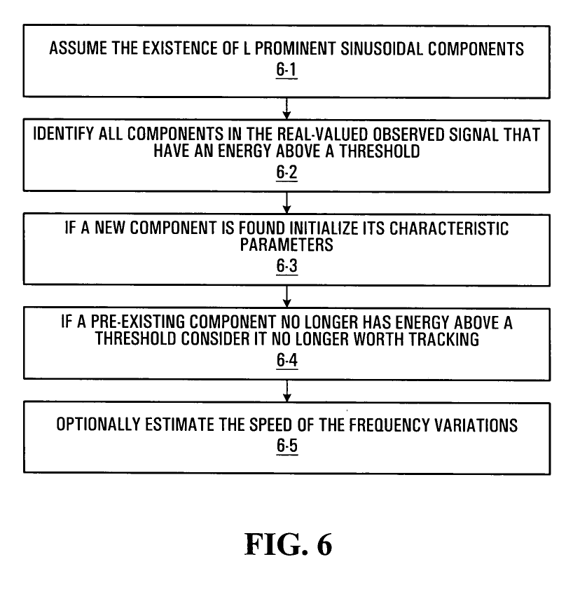

Referring to FIG. 6, the method begins at step 6-1 with the assumption that at the previous time instant n−1, L prominent sinusoidal components have been detected and are currently being tracked. The problem is further divided into the following test of hypotheses:

1) a previously tracked prominent sinusoidal component is still present or has diminished in energy to the point where it can no longer be considered a prominent component of the real-valued observed signal. In the latter case, the once-prominent sinusoidal component shall be considered to no longer exist within the real-valued observed signal and its corresponding parameters will be ignored (dropped) and no longer updated;

2) if a new prominent sinusoidal component has been detected within the real-valued observed signal, its frequency shall be initialized.

Thus step 6-2 is to compare the estimated energy within bands across the periodgram spectrum with a threshold. To calculate the periodgram, first over a frame of signal samples the Fast Fourier Transform of the input signal is calculated, and then the periodgram equals the squared absolute value of the results. The threshold is preferably proportional with \hat{σ}_{N}²(n) The estimate of noise energy, \hat{σ}_{N}²(n), is obtained by applying the signal

$${\vert {x}_{n - i} - {\sum }_{l = 1}^{L} Re ( {a}_{l} {ⅇ}^{{jω}_{l} ( n - i )} ) \vert}^{2}$$

to the lowpass filter wᵢ, as in (7). This allows the identification of all components in the real-valued signal which have an energy above the threshold.

In step 6-3 any newly-identified prominent sinusoidal components have their characteristic parameters initialized within the adaptive estimation and tracking method, as previously discussed.

If the energy of a previously tracked prominent sinusoidal component compared with the noise energy, \hat{σ}_{N}²(n), is very small, then it means that the corresponding component is no longer a prominent component of the real-valued observed signal and can be ignored by the rest of the method provided by the invention as indicated in step 6-4.

An additional step 6-5 can be used in the method to improve its performance by estimating the speed of frequency variations. The estimated speeds of the frequencies can be then used to overcome the crossover problem. When the frequencies of two components are not distant enough their separation may not be possible. Consequently, the algorithm may fail to track them properly. For each component, therefore, a test may be made to determine whether it is far enough apart from other frequencies. For each frequency component that is not far enough apart, instead of using the adaptive algorithm, the frequency algorithm can simply assume that the speed of the frequency variation is constant during the crossover.

The five steps 6-1, 6-2, 6-3, 6-4 and 6-5 of FIG. 6 need to be repeated often enough to keep track of components being added or dropped. The number of signal components might change often or not, and as such the rate of repetition should be selected depending on the application.

To apply the method to complex observed signals, the cross interference canceller would be a smaller matrix which deals with complex numbers instead, having dimensions half of what are required for real valued observed signals.

In another embodiment, with slight modifications the above-described methods/apparatuses can be used to estimate the chirp of each sinusoidal. Instead of equation (26) above, the following calculations are performed by the adaptive frequency tracker 160:

\tilde{ω}_{l,n}=\hat{ω}_{l,n}−μIm(Δ_{l,n}),

\hat{ξ}_{l,n}=(1−α)\hat{ξ}_{l,n-1}+α(\tilde{ω}_{l,n}−\tilde{ω}_{l,n-1}),

\hat{ω}_{l,n+1}=\tilde{ω}_{l,n}+\hat{ξ}_{l,n}. (28)

where ξ_{l,n} is the chirp (the speed of variation of the frequency). In the above frequency estimation procedure \hat{ω}_{l,n} is estimated as in (26). Then the variation of the estimated frequency in two successive time instant, i.e., (\hat{ω}_{l,n}−\hat{ω}_{l,n-1}) is applied to a lowpass filter that provides \hat{μ}_{l,n} as an estimate for the chirp parameter of the corresponding component. Finally, the frequency for next time iteration is predicted by a simple integrator that is the third equation in the above procedure.

In the case that the frequency varies smoothly with time the above procedure results in considerable improvement in frequency tracking at the expense of negligible computation. Examples of possible applications are wideband FM demodulation, speech frequency tracking, chirp estimation in some tracking radars, and several biomedical applications.

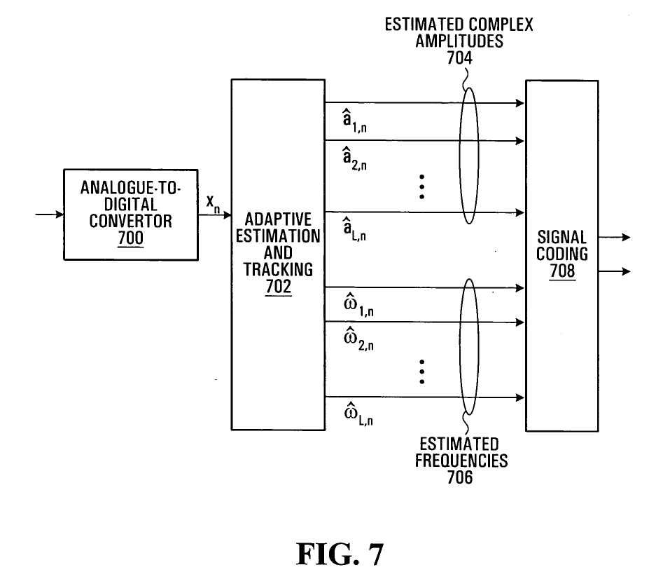

FIG. 7 is a block diagram of a speech coder provided by an embodiment of the invention. In this example, an input signal is first converted to digital form with analogue-to-digital converter 700 to produce the real-valued observed signal xₙ. This is processed by an adaptive estimation and tracking function 702 which operates in accordance with one of the previously described embodiments. The output of the adaptive estimation and tracking function 702 is a set of complex amplitudes 704 and a set of estimated frequencies 706. Together, amplitudes 704 and frequencies 706 are fed to a signal coding block 708 which encodes this information either for storage or transmission.

In the embodiments described, it is assumed that discreet signals are being processed and that the entire implementation is digital, requiring a D/A converter if the original signal is analogue. In another embodiment, the apparatus/method is implemented in the analogue domain directly eliminating any need for A/D conversion. The block diagram of such a system is basically the same as FIG. 1, except that the component extraction filters and frequency deviation filters are continuous time filters having continuous impulse responses. Instead of a discrete time signal function wₖ, a continuous time function Wt with similar properties should be used. Instead of the digital controlled oscillators 140, quadrature analogue voltage controlled oscillators are employed.

The adaptive frequency tracker 160 instead of employing a delay unit may use a simple integrator as following instead of (26)

$$\frac{ⅆ}{ⅆ t} {\hat{ω}}_{l , t} = - μ Im ( {Δ}_{l , t} ) . \qquad ( 29 )$$

Other changes are basically to use dual continuous-time elements equivalent to the corresponding digital elements that are described above.

In the embodiments described, it is assumed that cross-interference cancellation is performed, and this in generally will yield the best performance. In some embodiments of the invention, acceptable results may be realized without including cross-interference cancellation. For example, in processing signals having very little cross-interference, the cross-interference cancellation would provide only a small improvement.

In the embodiments described, complex envelope extraction is performed at the output to generate new sets of complex amplitude estimates. In some embodiments, complex envelope extraction can be omitted if a complex amplitude output is not required. In these embodiments, all the steps of complex envelope estimation are performed except the last step of extraction, since the output of this step is not fed back into other steps/components of the method/system.

In the embodiments described, it is assumed the same weighting function is employed for each of frequency tracking and amplitude tracking. More generally, a different weighting function may be employed for each of these purposes in which case a first weighting function is applied for frequency tracking, and a second weighting function is applied for amplitude estimation.

Simulations and Discussion

Simulations have been conducted for different signals. Firstly two scenarios are considered in order to study the performance of an example implementation of an embodiment of the invention for a signal with known components. The first scenario deals with the performance in different environments (SNR), for different signals (sinusoids and chirps) and also in the case of a cross-over. The second scenario studies the effect of the initialization and investigates the relationship between LIR and the length of the window. Then, the example implementation is applied to a speech signal as a multi-component stochastic signal, to study the performance for speech signals.

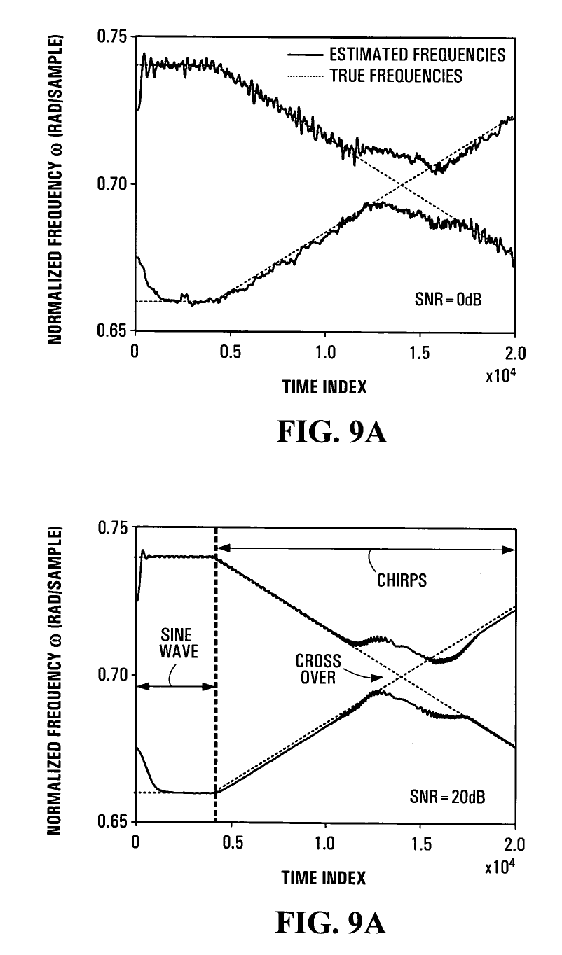

FIGS. 9A and 9B show the results of the first scenario where a signal with two components is considered. The frequencies of these components are time-dependent with a cross-over. This figure shows the performance of the algorithm in tracking sinusoids and crossing chirp components with constant amplitudes for SNR=0 in FIG. 9A and 20 dB in FIG. 9B. A Hamming window with length 129 was used. Initial points for frequencies are chosen close enough to the true values to ensure initial convergence, and the step-size is μ=10⁻⁴. The greater the step-size, the larger the variance of estimated frequencies and the lower the bias of the estimation. FIG. 9 clearly shows that the estimated values converge to the true values. In the chirp section, the algorithm tracks the components with a bias in the estimated frequencies. This bias/lag is a function of the window length; the shorter the window, the smaller the bias. For the chirp signals a shorter window is preferred, while for the sinusoidal signals a longer window works better. Around the cross-over moment, the performance degrades, since the two components are too close to each other so that they pass through the same filter and cannot be separated efficiently. In other words, the CIC is not able to cancel out the interference completely as the matrix F (Ω) becomes ill-conditioned. After the moment of cross-over, when the frequencies are far enough apart, the algorithm recovers the frequencies and tracks them again.

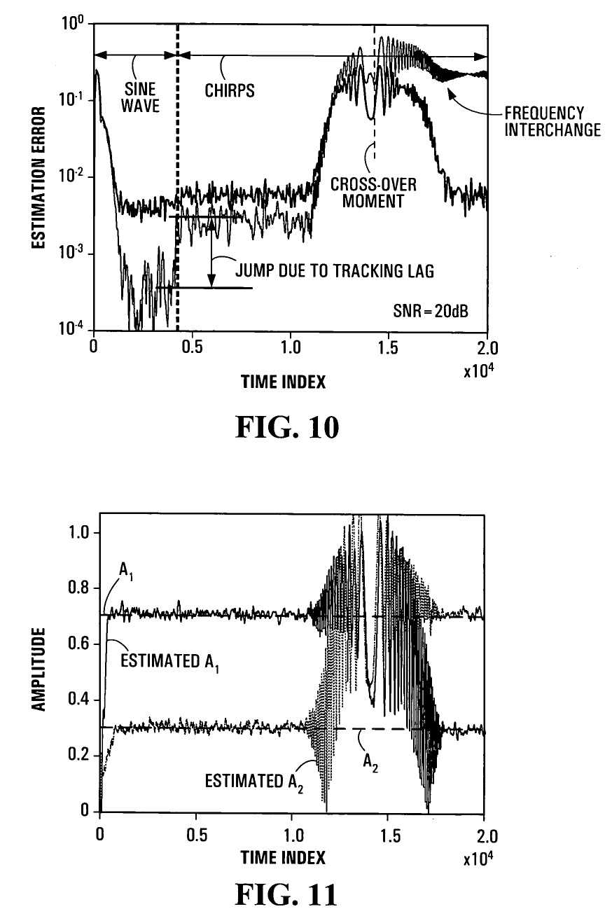

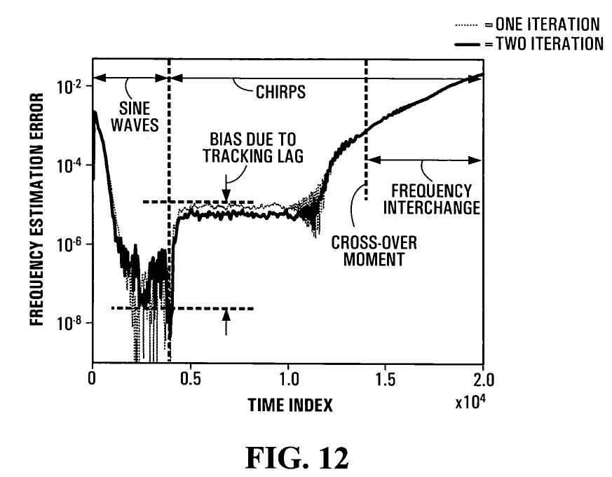

FIG. 10 supports the same results, where the estimation errors are plotted for SNR=20 dB. The effect of lag in the tracking of the chirp components is reflected in some bias in frequencies and a jump on the level of the MSE in both plots. FIG. 11 shows the magnitude of the estimated amplitudes and the true amplitudes. The estimated complex amplitudes are oscillatory with a very low frequency resulting from the estimation frequency lag, as they are the outputs of demodulators. These oscillations can be effectively smoothed by allying LPFs to the magnitude of the output of the demodulators, assuming a known bandwidth for true amplitudes. FIG. 12 shows the average of the squared frequency estimation error for two different implementations. The first one, the same version used in previous simulations, does the estimation/tracking process once in each time step. The second version employs a second additional iteration for each time step with a smaller step-size of μ₂=5×10⁻⁵. The algorithm with a second iteration provides a higher accuracy in tracking sinusoidal signals, as the error variance in frequency estimation is as low as 10⁻⁷. Due to the tracking lag for the chirp signals, there is a jump in the variance to 10⁻⁵. Around the moment of cross-over, the error increases. After the moment of cross-over the error is seen to increase due to the interchange of the frequencies. Using two iterations per time step, one gains shorter convergence period and less lag in chirp tracking at the expense of twice the computation.

FIGS. 9A, 9B, 10 and 11 show that there is an interchange between the components at the moment of cross-over, which the algorithm does not detect. On the other hand this interchange is reflected in the estimated amplitudes as shown in FIG. 11. Hence, using estimated amplitudes the cross-over moment is detectable and resolvable as long as the amplitudes are different.

The second scenario is defined in order to study the relationship between the window length and the LIR and was performed in different environments. Extensive simulations show that the LIR does not depend on the SNR (LIR measured with a resolution of 0.0011 fₛ where fₛ is the sampling frequency). For a specific window type, a shorter window length causes greater variances in tracking, because fewer signal samples are used in the estimation. At the same time, a shorter window length provides a wider LIR and results in a smaller bias. The tracking bias for the chirp component increases for longer windows, because the assumption of constant frequencies along the support of window becomes invalid.

For a specific window type, since this window determines the shape of all involved filters, the LIR is inversely proportional to the window length. For instance for a Hamming window the LIR is 0.015 and 0.027, when the window length is 129 and 65, respectively, where the frequencies are normalized with respect to fₛ. If the initial frequency error is greater than the LIR, then the convergence of the algorithm might take substantial time to fall in the LIR. Once the frequency estimation error is less than the LIR, the algorithm converges with a time constant controlled by the algorithm step-size.

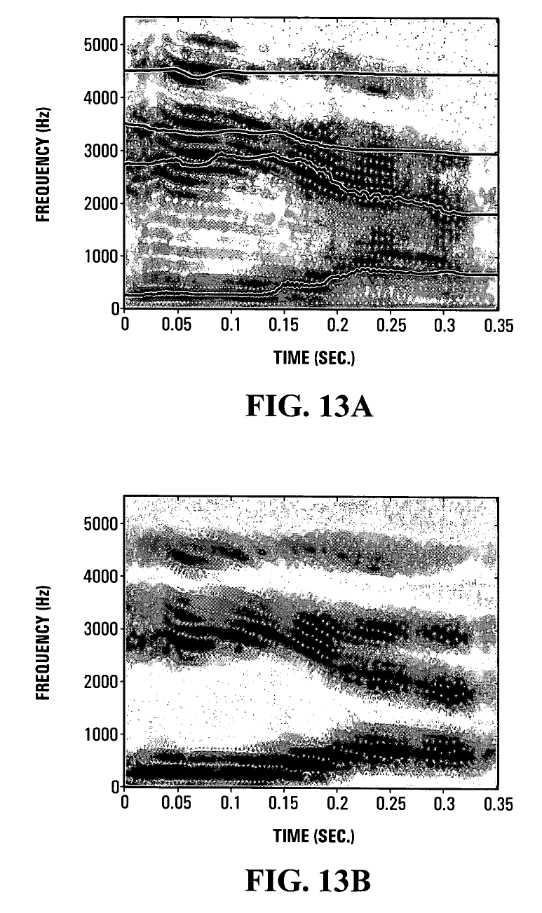

To study the performance of the algorithm for speech signals, a Hamming window of length 47 samples is used with four components of initial frequencies of 250, 2750, 3500 and 4500 Hz where the sampling frequency was 11025 Hz. The estimation/tracking process is implemented using two iterations per time step and two step sizes μ_{1,1} and μ_{2,1}=μ_{1,1}/3, respectively. Used step-sizes are μ_{1,1}=0.02 for the first component and 0.04 for all others. FIGS. 13A and 13B show the results obtained for a speech signal. FIG. 13A depicts the tracked frequencies on the spectrum background of the speech signal. Clearly, frequencies are tracking the dominant energy segments of the spectrum. FIG. 13B shows the spectrum of the constructed signal and supports how successful the algorithm is in decomposing stochastic signals.

What has been described is merely illustrative of the application of the principles of the invention. Other arrangements and methods can be implemented by those skilled in the art without departing from the spirit and scope of the present invention.

1. A method of tracking amplitude, phase and frequency of a plurality of sinusoidal components in a signal, the method comprising:
a) processing the signal to produce a new set of amplitude and phase estimates using a weighted likelihood method; and
b) processing the signal to produce a new set of frequency estimates using a weighted likelihood method.

2. A method according to claim 1 further comprising sampling the signal to produce a sequence of real-valued samples, wherein steps a) and b) are performed in the digital domain.

3. A method according to claim 1 further comprising sampling the signal to produce a sequence of complex-valued samples, wherein steps a) and b) are performed in the digital domain.

4. A method according to claim 1 wherein steps a) and b) are performed in the continuous time domain.

5. A method of tracking amplitude, phase and frequency of a plurality of sinusoidal components in a signal, the method comprising:
for a current update period:
i) processing the signal to produce a new set of complex amplitude estimates by:
a) for a first input set of estimated complex sinusoidal components, separating components to produce component estimates;
ii) processing the signal to produce a new set of estimated complex sinusoidal components by:
b) for each component of a second input set of estimated complex sinusoidal components, estimating a frequency deviation estimate;
c) adapting a previous set of frequency estimates taking into account an input set of component estimates and the frequency deviation estimates to produce a new set of frequency estimates; and
d) converting the new set of frequency estimates to a new set of estimated complex sinusoidal components.

6. A method according to claim 5 wherein the signal is a sequence of samples and processing is done in the digital domain.

7. A method according to claim 5 wherein the processing is done in the continuous time domain.

8. A method according to claim 5 further comprising:
performing cross-interference cancellation on the component estimates to produce a new set of cross-interference cancelled component estimates, and using the new set of cross-interference cancelled estimates as the input set of component estimates in an execution of step c).

9. A method according to claim 5 further comprising:
performing complex envelope extraction on the component estimates to produce a new set of complex amplitude estimates.

10. A method according to claim 8 further comprising:
performing complex envelope extraction on the cross-interference cancelled component estimates to produce a new set of complex amplitude estimates.

11. A method according to claim 6 wherein:
for the first input set of estimated complex sinusoidal components, separating components to produce component estimates is done using a weighted log-likelihood function with a first weighting sequence;
for each of the second input set of estimated complex sinusoidal components, estimating the frequency deviation estimate is done using a weighted log-likelihood function with a second weighting sequence.

12. A method according to claim 11 wherein the first and second weighting sequences are the same.

13. A method according to claim 9 wherein step i) comprises a first half-iteration, and step ii) comprises a second half iteration, one first half-iteration and one second half-iteration comprising a complete iteration and wherein for each update period, a plurality of complete iterations are performed to produce the new set of complex amplitude estimates and the new set of estimated complex sinusoidal components.

14. A method according to claim 5 wherein the first input set of estimated complex sinusoidal components and the second set of estimated complex sinusoidal components are initially set to initial values, and thereafter are set to estimated complex sinusoidal components produced by a previous iteration of the method.

15. A method according to claim 10 wherein for each update of the complex amplitude and frequency:
the step of processing samples of the sequence of samples to produce a new set of complex amplitude estimates is performed before the step of processing the sequence of samples to produce a new set of estimated complex sinusoidal components;
the first input set and the second input set of estimated complex sinusoidal components comprise the new set of estimated complex sinusoidal components determined during a previous update period;
wherein the input set of cross-interference cancelled estimates comprises the new set of cross-interference cancelled estimates determined during the current update period.

16. A method according to claim 10 wherein for each update of the amplitude, phase and frequency:
the step of processing the signal to produce a new set of estimated complex sinusoidal components is performed before the step of processing the sequence of samples to produce a new set of complex amplitude estimates;
the input set of component estimates comprises the set of cross-interference cancelled estimates determined during a previous update period;
the first input set of estimated complex sinusoidal components comprises the new set of estimated complex sinusoidal components determined during the current update period and the second input set of estimated complex sinusoidal components comprises the new set of estimated complex sinusoidal components determined during a previous update period.

17. A method according to claim 11 wherein for the first input set of estimated complex sinusoidal components, performing component extraction using a weighted log-likelihood function with the first weighting sequence comprises filtering the samples with a respective component extraction filter tuned to a respective one of the first input set of estimated complex sinusoidal components.

18. A method according to claim 8 wherein performing cross-interference cancellation on the component estimates to produce a new set of cross-interference cancelled component estimates comprises multiplying the component estimates by a cross-interference cancellation matrix.

19. A method according to claim 10 wherein performing complex envelope extraction on the cross-interference cancelled component estimates to produce the new set of complex amplitude estimates comprises multiplying each cross-interference cancelled component estimate by the respective estimated complex sinusoidal component with negative exponent.

20. A method according to claim 11 wherein for each of the second input set of estimated complex sinusoidal components, estimating a frequency deviation estimate using the weighted log-likelihood function with the second weighting sequence comprises filtering the sampled sequence with a respective frequency deviation filter tuned to the estimated complex sinusoidal component.

21. A method according to claim 5 wherein adapting the previous set of frequency estimates taking into account an input set of component estimates and the frequency deviation estimates to produce a new set of frequency estimates comprises applying an adaptation value to each previous frequency estimate, the adaptation value being a function of both the input set of component estimates and the frequency deviation estimates.

22. A method according to claim 21 wherein applying an adaptation value to each previous frequency estimate, the adaptation value being a function of both the input set of component estimates and the frequency deviation estimates comprises:
determining a partial derivative with respect to each estimated complex sinusoidal component of a function based on the weighted log-likelihood function;
for each frequency estimate, determining the adaptation value from the respective partial derivative.

23. A method according to claim 5 wherein adapting the previous set of frequency estimates taking into account the input set of component estimates and the frequency deviation estimates to produce the new set of frequency estimates comprises:
applying an adaptation value to each frequency estimate in the previous set of frequency estimates, the adaptation value being a function of both the component estimates and the frequency deviation estimates to produce an intermediate set of frequency estimates;
using the frequency deviation estimates and previous frequency deviation estimates to produce an estimate of chirp for each sinusoidal component;
for each sinusoidal component, combining the frequency deviation estimate and the estimate of chirp to produce a new frequency estimate.

24. A method according to claim 5 wherein converting the new set of frequency estimates to new estimated complex sinusoidal components comprises combining previous estimated complex sinusoidal component estimates with the new frequency estimates.

25. A method according to claim 24 wherein combining the previous estimated complex sinusoidal component estimates with the new frequency estimates comprises:
multiplying each previous estimated complex sinusoidal component estimate by e\hat{ }(j×new frequency estimate).

26. One or more ASICs (application specific integrated circuit) adapted to implement a method according claim 1.

27. One or more DSPs (digital signal processors) adapted to implement a method according to claim 1.

28. One or more FPGAs (field programmable gate arrays) adapted to implement a method according to claim 1.

29. One or more general purpose processors adapted to implement a method according to claim 1.

30. A combination of at least two circuits selected from a group consisting of ASIC, FPGA, DSP, and general purpose processor adapted to implement a method according to claim 1.

31. A computer readable medium having executable code embodied therein for causing a processing platform to execute a method according to claim 1.

32. An apparatus for tracking amplitude, phase and frequency of a plurality of sinusoidal components in a signal, the apparatus comprising:
a first processing path adapted to process the signal to produce a new set of amplitude and phase estimates using a weighted likelihood method; and
a second processing path adapted to process the signal to produce a new set of frequency estimates using a weighted likelihood method.

33. The apparatus according to claim 32 further comprising:
a sampler adapted to sample the signal to produce a sequence of real-valued samples, wherein the first and second processing paths perform signal processing in the digital domain.

34. An apparatus according to claim 32 further comprising:
a sampler adapted to sample the signal to produce a sequence of complex-valued samples, wherein the first and second processing paths perform signal processing in the digital domain.

35. An apparatus according to claim 32 wherein the first and second processing paths perform signal processing in the continuous time domain.

36. An apparatus for tracking amplitude, phase and frequency of a plurality of sinusoidal components in a signal, the apparatus comprising:
at least one component extraction filter adapted process the signal to produce component estimates for each of a first input set of estimated complex sinusoidal components, each component extraction filter being tuned to a respective one of the first input set of estimated complex sinusoidal components;
at least one frequency deviation filter adapted to process the signal to produce a frequency deviation estimate for each of a second input set of estimated complex sinusoidal components, each frequency deviation filter being tuned to a respective one of the second input set of estimated complex sinusoidal components;
at least one adaptive frequency tracker adapted to produce a new set of frequency estimates by adapting a previous set of frequency estimates taking into account an input set of component estimates and the frequency deviation estimates; and
at least one component generator adapted convert the new set of frequency estimates to a new set of estimated complex sinusoidal components.

37. An apparatus according to claim 36 wherein the signal is a sequence of samples and processing is done in the digital domain, and wherein the at least one component generator comprises at least one digital controlled oscillator.

38. An apparatus according to claim 36 further comprising:
a cross-interference canceller adapted to perform cross-interference cancellation on the component estimates to produce a new set of cross-interference cancelled component estimates;
wherein the new set of cross-interference cancelled estimates are used as the input set of component estimates to the adaptive frequency tracker.

39. An apparatus according to claim 36 further comprising:
at least one complex envelope estimator adapted to perform complex envelope extraction on the component estimates to produce a new set of complex amplitude estimates.

40. An apparatus according to claim 38 further comprising:
at least one complex envelope estimator adapted to perform complex envelope extraction on the cross-interference cancelled component estimates to produce a new set of complex amplitude estimates.

41. An apparatus according to claim 37 wherein:
each component extraction filter implements a weighted log-likelihood function with a first weighting sequence;
each frequency deviation filter implements a weighted log-likelihood function with a second weighting sequence.

42. An apparatus according to claim 41 wherein the first and second weighting sequences are the same.

43. An apparatus according to claim 36 wherein the first input set of estimated complex sinusoidal components and the second set of estimated complex sinusoidal components are initially set to initial values, and thereafter are set to previously determined estimated complex sinusoidal components.

44. An apparatus according to claim 38 wherein for each time a new set of complex amplitude estimates is produced by the apparatus:
the component extraction filter(s) operate to produce the new set of complex amplitude estimates before the frequency deviation filter(s) operate to produce the new set of estimated complex sinusoidal components;
the first input set and the second input set of estimated complex sinusoidal components comprise the new set of estimated complex sinusoidal components determined during a previous update period;
wherein the input set of cross-interference cancelled estimates comprises the new set of cross-interference cancelled estimates determined during the current update period.

45. An apparatus according to claim 38 wherein for each time a new set of complex amplitude estimates is produced by the apparatus:
the component extraction filter(s) operate to produce the new set of estimated complex sinusoidal components before the frequency deviation filters operate to produce the new set of complex amplitude estimates;
the input set of component estimates comprises the set of cross-interference cancelled estimates determined during a previous update period;
the first input set of estimated complex sinusoidal components comprises the new set of estimated complex sinusoidal components determined during the current update period and the second input set of estimated complex sinusoidal components comprises the new set of estimated complex sinusoidal components determined during a previous update period.

46. An apparatus according to claim 38 wherein the cross-interference canceller produces the new set of cross-interference cancelled component estimates by multiplying the component estimates by a cross-interference cancellation matrix.

47. An apparatus according to claim 40 wherein the complex envelope estimator(s) produce the new set of complex amplitude estimates by multiplying each cross-interference cancelled component estimate by the respective estimated complex sinusoidal component with negative exponent.

48. An apparatus according to claim 36 wherein the adaptive frequency tracker(s) apply an adaptation value to each previous frequency estimate, the adaptation value being a function of both the component estimates and the frequency deviation estimates.

49. An apparatus according to claim 48 wherein the adaptive frequency tracker(s) determine a partial derivative with respect to each estimated complex sinusoidal component of a function based on a weighted log-likelihood function and for each frequency estimate, determine the adaptation value from the respective partial derivative.

50. An apparatus according to claim 35 wherein the adaptive frequency tracker(s) produce a new set of frequency estimates by applying an adaptation value to each frequency estimate in a previous set of frequency estimates, the adaptation value being a function of both the component estimates and the frequency deviation estimates to produce an intermediate set of frequency estimates, and using the frequency deviation estimates and previous frequency deviation estimates to produce an estimate of chirp for each sinusoidal component, and for each sinusoidal component combine the frequency deviation estimate and the estimate of chirp to produce a new frequency estimate.

51. An apparatus according to claim 36 wherein the component generator(s) convert the new set of frequency estimates to new estimated complex sinusoidal components by combining previous estimated complex sinusoidal component estimates with the new frequency estimates.

52. A computer in combination with a computer readable medium compatible with the computer, cooperatively adapted to implement a method according to claim 1.
